(19) United States
(12) Patent Application Publication
(10) Pub. No.: US 2024/0315009 A1
(43) Pub. Date: Sep. 19, 2024

(54) SEMICONDUCTOR MEMORY DEVICE

(71) Applicant: SAMSUNG ELECTRONICS CO., LTD., Suwon-si (KR)

(72) Inventors: Jihoon KIM, Suwon-si (KR); Dohyung KIM, Suwon-si (KR); Youngjun KIM, Suwon-si (KR); Taekjung KIM, Suwon-si (KR); Yeonju OH, Suwon-s (KR); Jaejin LEE, Suwon-s (KR); Dongju CHANG, Suwon-si (KR); Seohyeong JANG, Suwon-si (KR)

(73) Assignee: SAMSUNG ELECTRONICS CO., LTD., Suwon-s (KR)

(21) Appl. No.: 18/386,916

(22) Filed: Nov. 3, 2023

(30) Foreign Application Priority Data
Mar. 17, 2023 (KR) 10-2023-0035054

(51) Int. Cl. H10B 12/00

(52) U.S. Cl. CPC H10B 12/34; H10B 12/053; H10B 12/315

(57) ABSTRACT

A semiconductor memory device is provided. The semiconductor memory device includes: an active pattern provided on a substrate and enclosed by a device isolation pattern; and a word line crossing the active pattern and the device isolation pattern in a first direction parallel to a bottom surface of the substrate, and including a first gate electrode and a second gate electrode, which are adjacent to each other in the first direction. A second work function of the second gate electrode is greater than a first work function of the first gate electrode.

### CROSS-REFERENCE TO RELATED APPLICATION

This application claims priority to Korean Patent Application No. 10-2023-0035054, filed on Mar. 17, 2023, in the Korean Intellectual Property Office, the disclosure of which is hereby incorporated by reference in its entirety.

### BACKGROUND

The present disclosure relates to a semiconductor device, and in particular, to a semiconductor memory device.

Due to their small-sized, multifunctional, and/or low-cost characteristics, semiconductor devices are important elements in the electronics industry. Types of semiconductor devices include a semiconductor memory device for storing data, a semiconductor logic device for processing data, and a hybrid semiconductor device including both of memory and logic elements.

Due to the recent increasing demand for electronic devices with a fast speed and/or low power consumption, the semiconductor device requires a fast operating speed and/or a low operating voltage. To satisfy the requirement, an integration density of the semiconductor device may be increased. As the integration density of the semiconductor device increases, the electrical and reliability characteristics of the semiconductor device may be deteriorated. Accordingly, many studies are being conducted to improve the electrical and reliability characteristics of the semiconductor device.

### SUMMARY

One or more embodiments provide a semiconductor memory device with improved electrical and reliability characteristics.

According to an aspect of an embodiment, a semiconductor memory device includes: an active pattern provided on a substrate and enclosed by a device isolation pattern; and a word line crossing the active pattern and the device isolation pattern in a first direction parallel to a bottom surface of the substrate, and including a first gate electrode and a second gate electrode, which are adjacent to each other in the first direction. A second work function of the second gate electrode is greater than a first work function of the first gate electrode.

According to an aspect of an embodiment, a semiconductor memory device includes: an active pattern provided on a substrate and enclosed by a device isolation pattern; a first gate electrode crossing the active pattern and the device isolation pattern in a first direction parallel to a bottom surface of the substrate; and a second gate electrode extending through the first gate electrode along a vertical direction perpendicular to the bottom surface of the substrate. The first gate electrode is provided around a side surface of the second gate electrode, and a second work function of the second gate electrode is greater than a first work function of the first gate electrode.

According to an aspect of an embodiment, a semiconductor memory device includes: an active pattern provided on a substrate and enclosed by a device isolation pattern; a word line crossing the active pattern and the device isolation pattern in a first direction parallel to a bottom surface of the substrate, the word line including a first gate electrode and a second gate electrode, which are adjacent to each other in the first direction; a bit line provided on the active pattern and extended in a second direction crossing the first direction; a bit line contact between the active pattern and the bit line; a storage node contact on the active pattern; a landing pad on the storage node contact; and a data storage pattern on the landing pad. A second work function of the second gate electrode is greater than a first work function of the first gate electrode.

### BRIEF DESCRIPTION OF DRAWINGS

The above and other aspects will be more apparent from the following description of example embodiments taken in conjunction with the accompanying drawings.

FIG. 1 is a block diagram illustrating a semiconductor memory device according to an embodiment.

FIG. 2 is a plan view illustrating a semiconductor memory device according to an embodiment and corresponding to a portion ‘P1’ of FIG. 1.

FIGS. 3A, 3B and 3C are sectional views, which are respectively taken along lines A-A′, B-B′, and C-C′ of FIG. 2 to illustrate a semiconductor memory device according to an embodiment.

FIG. 4A is an enlarged sectional view corresponding to a portion ‘P2’ of FIG. 3A, and FIG. 4B is an enlarged sectional view corresponding to a portion ‘P3’ of FIG. 3B.

FIGS. 5A and 5B are sectional views, which are respectively taken along the lines A-A′ and B-B′ of FIG. 2 to illustrate a semiconductor memory device according to an embodiment.

FIG. 6A is an enlarged sectional view corresponding to a portion ‘P2’ of FIG. 5A, and FIG. 6B is an enlarged sectional view corresponding to a portion ‘P3’ of FIG. 5B.

FIGS. 7A and 7B are sectional views, which are respectively taken along the lines A-A′ and B-B′ of FIG. 2 to illustrate a semiconductor memory device according to an embodiment.

FIG. 8A is an enlarged sectional view corresponding to a portion ‘P2’ of FIG. 7A, and FIG. 8B is an enlarged sectional view corresponding to a portion ‘P3’ of FIG. 7B.

FIGS. 9A and 9B are sectional views, which are respectively taken along the lines A-A′ and B-B′ of FIG. 2 to illustrate a semiconductor memory device according to an embodiment.

FIG. 10A is an enlarged sectional view corresponding to a portion ‘P2’ of FIG. 9A, and FIG. 10B is an enlarged sectional view corresponding to a portion ‘P3’ of FIG. 9B.

FIGS. 11A and 11B are sectional views, which are respectively taken along the lines A-A′ and B-B′ of FIG. 2 to illustrate a semiconductor memory device according to an embodiment.

FIG. 12A is an enlarged sectional view corresponding to a portion ‘P2’ of FIG. 11A, and FIG. 12B is an enlarged sectional view corresponding to a portion ‘P3’ of FIG. 11B.

FIG. 13A is a plan view illustrating a semiconductor memory device according to an embodiment and corresponding to the portion ‘P1’ of FIG. 1. FIG. 13B is an enlarged sectional view corresponding to a word line of FIG. 13A.

FIG. 14 is a sectional view taken along a line B-B′ of FIG. 13A to illustrate a semiconductor memory device according to an embodiment.

FIG. 15 is an enlarged sectional view corresponding to a portion ‘P3’ of FIG. 14.

FIG. 16 is a sectional view taken along the line B-B′ of FIG. 13A to illustrate a semiconductor memory device according to an embodiment.

FIG. 17 is an enlarged sectional view corresponding to a portion ‘P3’ of FIG. 16.

FIG. 18 is a sectional view taken along the line B-B′ of FIG. 13A to illustrate a semiconductor memory device according to an embodiment.

FIG. 19 is an enlarged sectional view corresponding to a portion ‘P3’ of FIG. 18.

FIGS. 20A, 20B, 21A, 21B, 22A, 22B, 23A, 23B, 24A, 24B, 25A and 25B are sectional views illustrating a method of fabricating a semiconductor memory device, according to an embodiment.

FIGS. 26A, 26B, 27A and 27B are sectional views illustrating a method of fabricating a semiconductor memory device, according to an embodiment.

FIGS. 28A, 28B, 29A, 29B, 30A and 30B are sectional views illustrating a method of fabricating a semiconductor memory device, according to an embodiment.

FIGS. 31A, 31B, 32A and 32B are sectional views illustrating a method of fabricating a semiconductor memory device, according to an embodiment.

FIGS. 33 and 34 are sectional views illustrating a method of fabricating a semiconductor memory device, according to an embodiment.

### DETAILED DESCRIPTION

Example embodiments will now be described more fully with reference to the accompanying drawings, in which example embodiments are shown. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

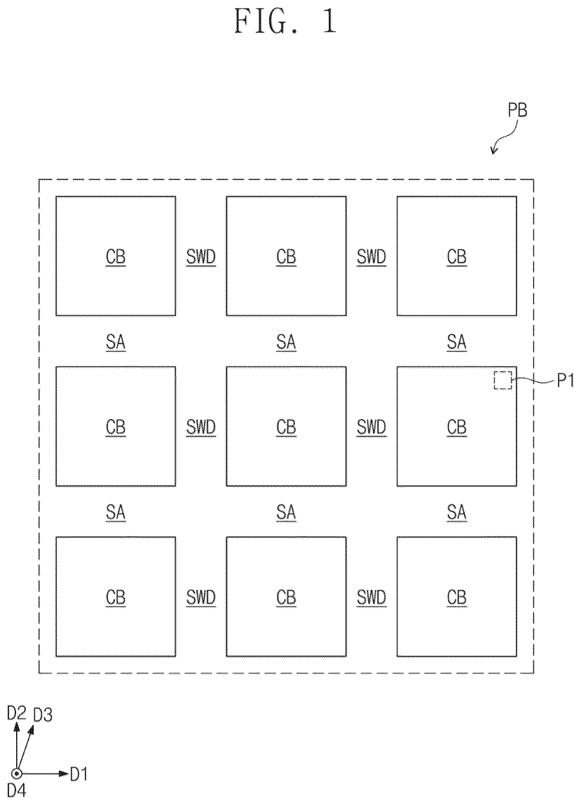

FIG. 1 is a block diagram illustrating a semiconductor memory device according to an embodiment.

Referring to FIG. 1, a semiconductor memory device may include cell blocks CB and a peripheral block PB, which is provided around each of the cell blocks CB. Each of the cell blocks CB may include a cell circuit, such as a memory integrated circuit. The peripheral block PB may include various peripheral circuits, which are used to operate the cell circuit, and the peripheral circuits may be electrically connected to the cell circuit.

The peripheral block PB may include sense amplifier circuits SA and sub-word line driver circuits SWD. In an embodiment, the sense amplifier circuits SA may be provided to face each other, with the cell blocks CB interposed therebetween, and the sub-word line driver circuits SWD may be provided to face each other, with the cell blocks CB interposed therebetween. The peripheral block PB may further include power and ground circuits for driving a sense amplifier, but embodiments are not limited thereto.

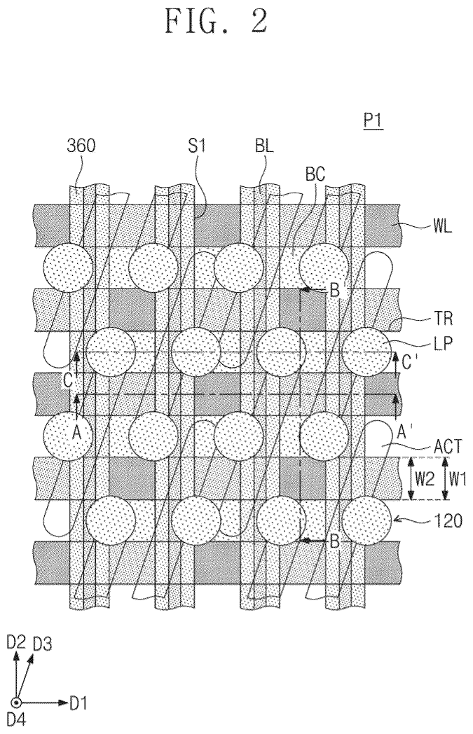

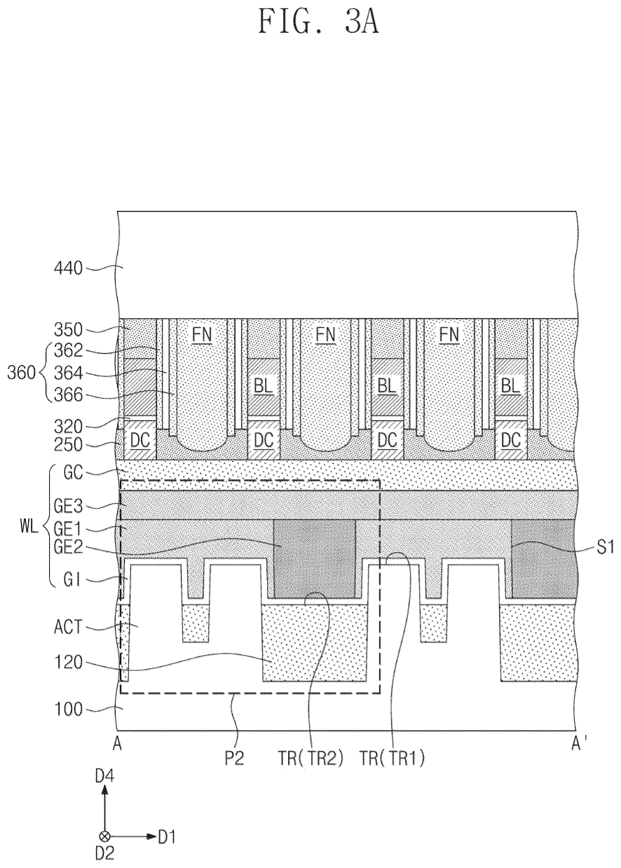

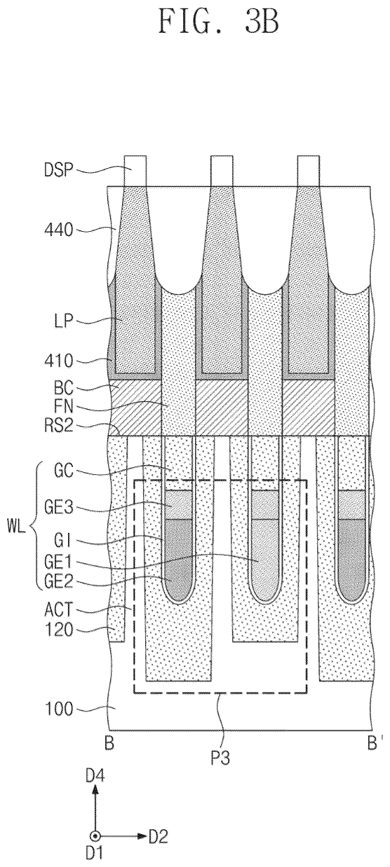

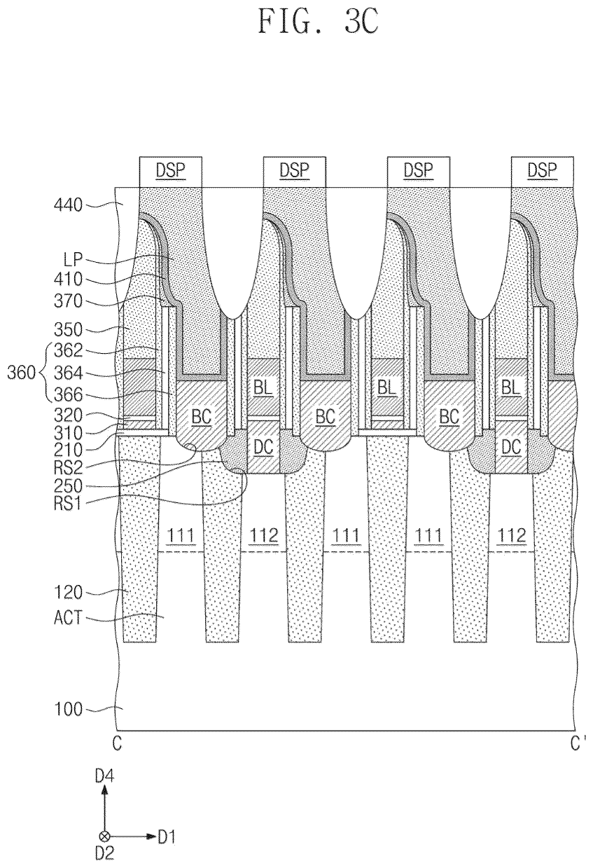

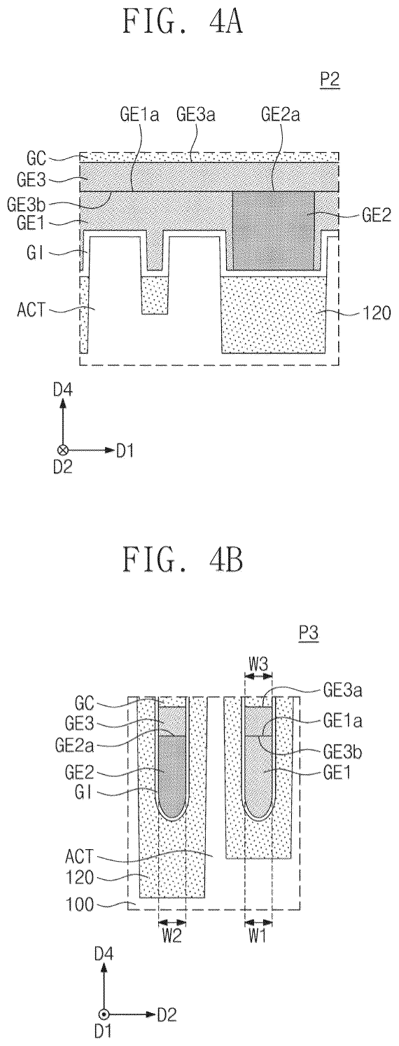

FIG. 2 is a plan view illustrating a semiconductor memory device according to an embodiment and corresponding to a portion ‘P1’ of FIG. 1. FIGS. 3A to 3C are sectional views, which are respectively taken along lines A-A′, B-B′, and C-C′ of FIG. 2 to illustrate a semiconductor memory device according to an embodiment. FIG. 4A is an enlarged sectional view corresponding to a portion ‘P2’ of FIG. 3A, and FIG. 4B is an enlarged sectional view corresponding to a portion ‘P3’ of FIG. 3B.

Referring to FIGS. 2 to 4B, a substrate 100 may be provided. The substrate 100 may be a semiconductor substrate (e.g., a silicon wafer, a germanium wafer, or a silicon-germanium wafer).

A device isolation pattern 120 may be disposed on the substrate 100 to define active patterns ACT. The active patterns ACT may be provided on the cell blocks CB of FIG. 1. The active patterns ACT may be spaced apart from each other in a first direction D1 and a second direction D2, which are non-parallel (e.g., perpendicular) to each other. The first and second directions D1 and D2 may be parallel to a bottom surface of the substrate 100. The active patterns ACT may be bar-shaped patterns, which are spaced apart from each other, resembling islands, and are elongated in a third direction D3. The third direction D3 may be parallel to the bottom surface of the substrate 100 and may be non-parallel to the first and second directions D1 and D2.

The active patterns ACT may be protruded in a fourth direction D4 perpendicular to the bottom surface of the substrate 100. In an embodiment, the device isolation pattern 120 may be disposed in the substrate 100, and the active patterns ACT may be portions of the substrate 100 enclosed by the device isolation pattern 120. For the sake of convenience in explanation, the term “substrate 100” may refer to the remaining portion of the substrate 100, excluding the active patterns ACT, unless otherwise stated.

The device isolation pattern 120 may be formed of or include at least one of various insulating materials (e.g., silicon oxide, silicon nitride, or combinations thereof). The device isolation pattern 120 may be a single layer, which is made of a single material, or a composite layer including two or more materials. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements. For example, the expression, “at least one of A, B, and C,” should be understood as including only A, only B, only C, both A and B, both A and C, both B and C, or all of A, B, and C.

Each of the active patterns ACT may include a pair of edge portions 111 and a center portion 112. The pair of edge portions 111 may be opposite end portions of the active pattern ACT in the third direction D3. The center portion 112 may be a portion of the active pattern ACT, which is interposed between the paired edge portions 111, specially, between a pair of word lines WL that will be described below. The pair of edge portions 111 and/or the center portion 112 may be doped with impurities to have an n-type conductivity or p-type conductivity.

A word line WL may be disposed to cross the active patterns ACT. As an example, the word line WL may cross the active patterns ACT and the device isolation pattern 120 in the first direction D1. In an embodiment, a plurality of word lines WL may be provided. The word lines WL may be spaced apart from each other in the second direction D2. In an embodiment, a pair of the word lines WL, which are adjacent to each other in the second direction D2, may be provided to cross the active patterns ACT thereunder.

The word line WL may be disposed within a trench region TR, which is formed to cross the active patterns ACT and the device isolation pattern 120. The trench region TR may be extended in the first direction D1. The trench region TR may include a first trench region TR1 and a second trench region TR2. A bottom surface of the first trench region TR1 may be disposed at a level higher than a bottom surface of the second trench region TR2. Here, the term “level” may be defined as a height measured from the bottom surface of the substrate 100, and may correspond of the fourth direction D4. The first trench region TR1 may be disposed on the active patterns ACT, and the second trench region TR2 may be disposed on the device isolation pattern 120.

Each of the word lines WL may include a first gate electrode GE1, a second gate electrode GE2, a third gate electrode GE3, a gate insulating pattern GI, and a gate capping pattern GC. The first gate electrode GE1, the second gate electrode GE2, the third gate electrode GE3, the gate insulating pattern GI, and the gate capping pattern GC will be described in more detail below.

The first gate electrode GE1 and the second gate electrode GE2 may be adjacent to each other in the first direction D1. As an example, the second gate electrode GE2 may be placed on a first side surface S1 of the first gate electrode GE1. Here, the first side surface S1 may be a side surface of the first gate electrode GE1 that faces the first direction D1 or an opposite direction of the first direction D1. The first and second gate electrodes GE1 and GE2 may be connected to each other. In the present specification, the expression “A is connected to B” may be used to not only represent “A is in contact with B” but also represent that “A is electrically connected to B” although they are not in physical contact with each other.

In an embodiment, in a pair of the word lines WL crossing each active pattern ACT, the first gate electrode GE1 of one of the paired word lines WL and the second gate electrode GE2 of the other may be adjacent to each other in the second direction D2.

The first gate electrode GE1 may include a plurality of first gate electrodes GE1, and the second gate electrode GE2 may include a plurality of second gate electrodes GE2. The first gate electrodes GE1 and the second gate electrodes GE2 may be alternately disposed in the first direction D1. The first gate electrodes GE1 and the second gate electrodes GE2 may be alternately disposed such that they are adjacent to each other in the second direction D2.

The first and second gate electrodes GE1 and GE2 may include top surfaces GE1a and GE2a, respectively. In an embodiment, a level of the top surface GE1a of the first gate electrode GE1 may be substantially equal to a level of the top surface GE2a of the second gate electrode GE2.

The top surface GE1a of the first gate electrode GE1 may have a first width W1 in the second direction D2. The top surface GE2a of the second gate electrode GE2 may have a second width W2 in the second direction D2. In an embodiment, the first and second widths W1 and W2 may be substantially equal to each other.

Each of the first and second gate electrodes GE1 and GE2 may include a bottom surface. A level of the bottom surface of the first gate electrode GE1 may be substantially equal to or higher than a level of the bottom surface of the second gate electrode GE2.

The third gate electrode GE3 may be placed on the first gate electrode GE1 and the second gate electrode GE2. As an example, the third gate electrode GE3 may cover the top surface GE1a of the first gate electrode GE1 and may be extended in the first direction D1 to a region on the top surface GE2a of the second gate electrode GE2. The first gate electrode GE1 may be interposed between the third gate electrode GE3 and the active pattern ACT. Each of the first and second gate electrodes GE1 and GE2 may be interposed between the third gate electrode GE3 and the device isolation pattern 120. In an embodiment, the first, second, and third gate electrodes GE1, GE2, and GE3 may be connected to each other. A blocking layer may be provided between two electrodes, which are selected from the first, second, and third gate electrodes GE1, GE2, and GE3. As an example, the blocking layer may be a single layer or a composite layer.

The third gate electrode GE3 may include a top surface GE3a. The top surface GE3a of the third gate electrode GE3 may have a third width W3 in the second direction D2. Each of the first and second widths W1 and W2 may be substantially equal to or smaller than the third width W3.

The first, second, and third gate electrodes GE1, GE2, and GE3 may be formed of or include different materials from each other. Each of the first and second gate electrodes GE1 and GE2 may be formed of or include at least one of Ti, TiN, TiSiN, TiON, W, WN, Mo, MoN, MoOₓN_{y}, Ta, TaN, or poly Si. The third gate electrode GE3 may be formed of or include impurity-doped polysilicon. In an embodiment, each of the first, second, and third gate electrodes GE1, GE2, and GE3 may be a single layer or a composite layer.

The first, second, and third gate electrodes GE1, GE2, and GE3 may have different work functions from each other. The work function of the first gate electrode GE1 will be referred to as a first work function. The work function of the second gate electrode GE2 will be referred to as a second work function. The work function of the third gate electrode GE3 will be referred to as a third work function. In an embodiment, the first work function of the first gate electrode GE1 may be smaller than the second work function of the second gate electrode GE2. As an example, the first work function of the first gate electrode GE1 may be equal to or less than 4.5 eV. The second work function of the second gate electrode GE2 may be equal to or greater than 4.6 eV. In an embodiment, the first work function of the first gate electrode GE1 may be greater than the third work function of the third gate electrode GE3. The second work function of the second gate electrode GE2 may be greater than the third work function of the third gate electrode GE3.

In an embodiment, in the word lines WL which are adjacent to each other in the second direction D2, the first gate electrode GE1 of one of the word lines WL and the second gate electrode GE2 of the other may be adjacent to each other in the second direction D2. The second work function of the second gate electrode GE2 may be greater than the first work function of the first gate electrode GE1. Accordingly, an electric interference issue between the adjacent ones of the word lines WL may be reduced. As a result, the electrical and reliability characteristics of the semiconductor memory device may be improved.

The first, second, and third gate electrodes GE1, GE2, and GE3 may have different resistivities from each other. As an example, the resistivity of the first gate electrode GE1 may be greater than the resistivity of the second gate electrode GE2, and the resistivity of the third gate electrode GE3 may be greater than the resistivity of the first gate electrode GE1. In an embodiment, the second gate electrode GE2, which has a relatively smaller resistivity than the first gate electrode GE1, may be provided on the side surface of the first gate electrode GE1, which faces the first direction D1. Accordingly, an electric resistance of the word line WL may be reduced. As a result, the electrical characteristics of the semiconductor memory device may be improved.

The first gate electrode GE1 may be placed on the active pattern ACT and the device isolation pattern 120. The first gate electrode GE1 may be placed on the first and second trench regions TR1 and TR2. In an embodiment, the first gate electrode GE1 may fill a lower portion of each of the first and second trench regions TR1 and TR2.

The second gate electrode GE2 may be placed on the device isolation pattern 120. The second gate electrode GE2 may be placed on the second trench region TR2. As an example, the second gate electrode GE2 may fill a lower portion of the second trench region TR2. The second gate electrode GE2 may be interposed between the active patterns ACT, which are adjacent to each other in the third direction D3. The second gate electrode GE2 may be interposed between the active patterns ACT, which are adjacent to each other in a clockwise direction. The second gate electrode GE2 may be interposed between the first trench regions TR1, which are adjacent to each other in the first direction D1.

The third gate electrode GE3 may be placed on the active pattern ACT and the device isolation pattern 120. The third gate electrode GE3 may be placed on the first and second trench regions TR1 and TR2. In an embodiment, the third gate electrode GE3 may partially fill the first and second trench regions TR1 and TR2.

The gate insulating pattern GI may conformally cover an inner surface of the trench region TR. The gate insulating pattern GI may be interposed between the first gate electrode GE1 and the active pattern ACT. The gate insulating pattern GI may be interposed between the first gate electrode GE1 and the device isolation pattern 120. The gate insulating pattern GI may be interposed between the second gate electrode GE2 and the device isolation pattern 120. In an embodiment, the gate insulating pattern GI may be formed of or include at least one of silicon oxide or various high-k dielectric materials.

The gate capping pattern GC may fill an upper portion of the trench region TR. The gate capping pattern GC may be disposed on the top surface GE3a of the third gate electrode GE3. The gate capping pattern GC may be spaced apart from each of the first and second gate electrodes GE1 and GE2 by the third gate electrode GE3. In an embodiment, the gate capping pattern GC may be formed of or include silicon nitride.

A buffer pattern 210 may be disposed on the substrate 100. The buffer pattern 210 may cover the active patterns ACT, the device isolation pattern 120, and the word lines WL. In an embodiment, the buffer pattern 210 may be formed of or include at least one of silicon oxide, silicon nitride, or silicon oxynitride. The buffer pattern 210 may be a single layer, which is made of a single material, or a composite layer including two or more materials.

A bit line contact DC may be provided on each of the active patterns ACT, and in an embodiment, a plurality of bit line contacts DC may be provided. The bit line contacts DC may be connected to the center portions 112 of the active patterns ACT, respectively. The bit line contacts DC may be spaced apart from each other in the first and second directions D1 and D2. The bit line contact DC may be interposed between each of the active patterns ACT and a corresponding one of bit lines BL, which will be described below. Each of the bit line contacts DC may connect a corresponding one of the bit lines BL to the center portion 112 of a corresponding one of the active patterns ACT.

The bit line contacts DC may be disposed in first recess regions RS1, respectively. The first recess regions RS1 may be provided in upper portions of the active patterns ACT and an upper portion of the device isolation pattern 120, which is adjacent to the upper portions of the active patterns ACT. The first recess regions RS1 may be spaced apart from each other in the first and second directions D1 and D2.

A gapfill insulating pattern 250 may fill each of the first recess regions RS1. The gapfill insulating pattern 250 may fill an inner space of the first recess region RS1. As an example, the gapfill insulating pattern 250 may cover an inner surface of the first recess region RS1 and at least a portion of a side surface of the bit line contact DC (e.g., in the first recess region RS1). The gapfill insulating pattern 250 may be formed of or include at least one of silicon oxide or silicon nitride. The gapfill insulating pattern 250 may be a single layer, which is made of a single material, or a composite layer including two or more materials.

The bit line BL may be provided on the bit line contact DC. The bit line BL may be extended in the second direction D2. The bit line BL may be disposed on the bit line contacts DC, which are arranged in the second direction D2 to form a line. In an embodiment, a plurality of bit lines BL may be provided. The bit lines BL may be spaced apart from each other in the first direction D1. The bit line BL may be formed of or include at least one of various metallic materials. As an example, the bit line BL may be formed of or include at least one of tungsten, rubidium, molybdenum, or titanium.

A polysilicon pattern 310 may be provided between the bit line BL and the buffer pattern 210 and between the bit line contacts DC, which are adjacent to each other in the second direction D2. In an embodiment, a plurality of polysilicon patterns 310 may be provided. The polysilicon patterns 310 may be spaced apart from each other in the first direction D1 and the second direction D2. A top surface of the polysilicon pattern 310 may be located at substantially the same height as a top surface of the bit line contact DC and may be coplanar with the top surface of the bit line contact DC. The polysilicon pattern 310 may be formed of or include doped polysilicon.

A first ohmic pattern 320 may be provided between the bit line BL and the bit line contact DC and between the bit line BL and the polysilicon pattern 310. The first ohmic pattern 320 may be extended along the bit lines BL and in the second direction D2. In an embodiment, a plurality of first ohmic patterns 320 may be provided. The first ohmic patterns 320 may be spaced apart from each other in the first direction D1. The first ohmic pattern 320 may be formed of or include at least one of various metal silicide materials. A first barrier pattern may be further interposed between the bit line BL and the bit line contact DC and between the bit line BL and the polysilicon pattern 310. The first barrier pattern may be formed of or include at least one of various conductive metal nitride materials (e.g., titanium nitride and tantalum nitride).

A bit line capping pattern 350 may be provided on a top surface of the bit line BL. On the top surface of the bit line BL, the bit line capping pattern 350 may be extended in the second direction D2. In an embodiment, a plurality of bit line capping patterns 350 may be provided. The bit line capping patterns 350 may be spaced apart from each other in the first direction D1. The bit line capping pattern 350 may be vertically overlapped with the bit line BL. The bit line capping pattern 350 may be composed of a single layer or a plurality of layers. As an example, the bit line capping pattern 350 may include a first capping pattern, a second capping pattern, and a third capping pattern, which are sequentially stacked. The first to third capping patterns may be formed of or include silicon nitride. As another example, the bit line capping pattern 350 may include a plurality of capping patterns, which are stacked to form four or more layers.

A bit line spacer 360 may be provided on a side surface of the bit line BL and a side surface of the bit line capping pattern 350. The bit line spacer 360 may cover the side surface of the bit line BL and the side surface of the bit line capping pattern 350. The bit line spacer 360 on the side surface of the bit line BL may be extended in the second direction D2. In an embodiment, a plurality of bit line spacers 360 may be provided. The bit line spacers 360 may be spaced apart from each other in the first direction D1.

Each of the bit line spacers 360 may include a plurality of spacers. As an example, each of the bit line spacers 360 may include a first spacer 362, a second spacer 364, and a third spacer 366. The third spacer 366 may be provided on the side surface of the bit line BL and the side surface of the bit line capping pattern 350. The first spacer 362 may be interposed between the bit line BL and the third spacer 366 and between the bit line capping pattern 350 and the third spacer 366. The second spacer 364 may be interposed between the first spacer 362 and the third spacer 366. In an embodiment, each of the first to third spacers 362, 364, and 366 may be independently formed of or include at least one of silicon nitride, silicon oxide, or silicon oxynitride. As another example, the second spacer 364 may include an air gap separating the first and third spacers 362 and 366 from each other.

A capping spacer 370 may be placed on the bit line spacer 360. The capping spacer 370 may cover an upper portion of a side surface of the bit line spacer 360. In an embodiment, the capping spacer 370 may be formed of or include silicon nitride.

A storage node contact BC may be provided between adjacent ones of the bit lines BL. As an example, the storage node contact BC may be interposed between adjacent ones of the bit line spacers 360. In an embodiment, a plurality of storage node contacts BC may be provided. The storage node contacts BC may be spaced apart from each other in the first and second directions D1 and D2. The storage node contacts BC may be spaced apart from each other in the second direction D2 by fence patterns FN on the word lines WL. The fence pattern FN may be provided between adjacent ones of the bit lines BL. In an embodiment, a plurality of fence patterns FN may be provided. The fence patterns FN may be spaced apart from each other in the first and second directions D1 and D2. The fence patterns FN, which are adjacent to each other in the first direction D1, may be spaced apart from each other, with the bit line BL interposed therebetween. The fence patterns FN, which are adjacent to each other in the second direction D2, may be spaced apart from each other, with the storage node contact BC interposed therebetween. In an embodiment, the fence patterns FN may be formed of or include silicon nitride.

The storage node contact BC may fill a second recess region RS2, which is provided on the edge portion 111 of the active pattern ACT. The storage node contact BC may be connected to the edge portion 111. The storage node contact BC may be formed of or include at least one of doped or undoped polysilicon or various metallic materials.

A second barrier pattern 410 may conformally cover the bit line spacer 360, the fence pattern FN, and the storage node contact BC. The second barrier pattern 410 may be formed of or include at least one of various metal nitride materials (e.g., titanium nitride and tantalum nitride). A second ohmic pattern may be further interposed between the second barrier pattern 410 and the storage node contact BC. The second ohmic pattern may be formed of or include at least one of various metal silicide materials.

A landing pad LP may be provided on the storage node contact BC. In an embodiment, a plurality of landing pads LP may be provided. The landing pads LP may be spaced apart from each other in the first and second directions D1 and D2. Each of the landing pads LP may be connected to a corresponding one of the storage node contacts BC. The landing pad LP may cover a top surface of the bit line capping pattern 350. A lower region of the landing pad LP may be vertically overlapped with the storage node contact BC. An upper region of the landing pad LP may be shifted from the lower region in the first direction D1. The landing pad LP may be formed of or include at least one of various metallic materials (e.g., tungsten, titanium, and tantalum).

A filler pattern 440 may be provided to enclose the landing pad LP. The filler pattern 440 may be interposed between adjacent ones of the landing pads LP. When viewed in a plan view, the filler pattern 440 may be provided in a mesh shape with holes, and in this case, the landing pads LP may be provided in the holes to penetrate the filler pattern 440. As an example, the filler pattern 440 may be formed of or include at least one of silicon nitride, silicon oxide, or silicon oxynitride. As another example, the filler pattern 440 may include an empty space with an air layer (i.e., an air gap).

A data storage pattern DSP may be provided on the landing pad LP. In an embodiment, a plurality of data storage patterns DSP may be provided. The data storage patterns DSP may be spaced apart from each other in the first and second directions D1 and D2. Each of the data storage patterns DSP may be connected to a corresponding one of the edge portions 111 through a corresponding one of the landing pads LP and a corresponding one of the storage node contacts BC.

As an example, the data storage pattern DSP may be a capacitor including a bottom electrode, a dielectric layer, and a top electrode. In this case, the semiconductor memory device may be a dynamic random access memory (DRAM) device. As another example, the data storage pattern DSP may include a magnetic tunnel junction pattern. In this case, the semiconductor memory device may be a magnetic random access memory (MRAM) device. As other examples, the data storage pattern DSP may include a phase-change material or a variable resistance material. In this case, the semiconductor memory device may be a phase-change random access memory (PRAM) device or a resistive random access memory (ReRAM) device. However, embodiments are not limited to these examples, and the data storage pattern DSP may include various structures and/or materials that can be used to store data therein.

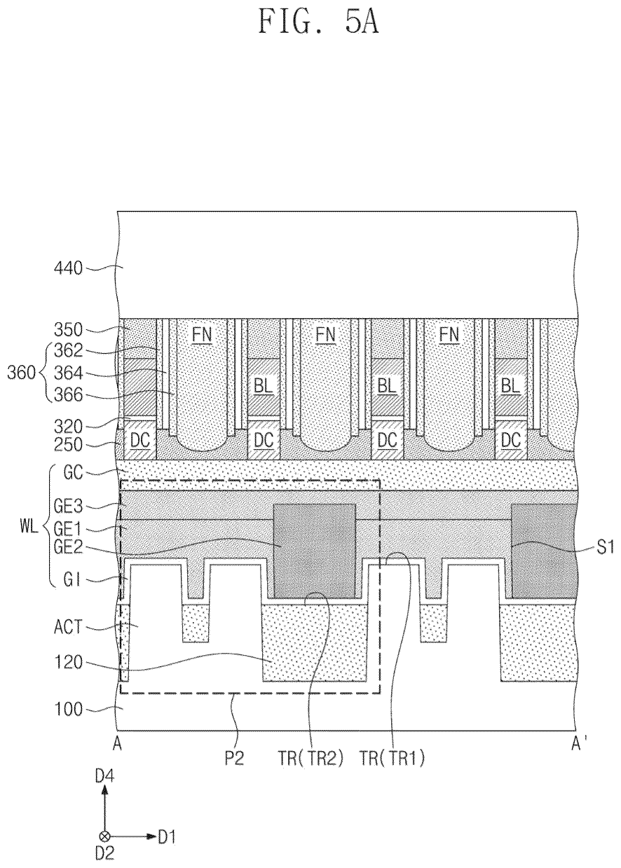

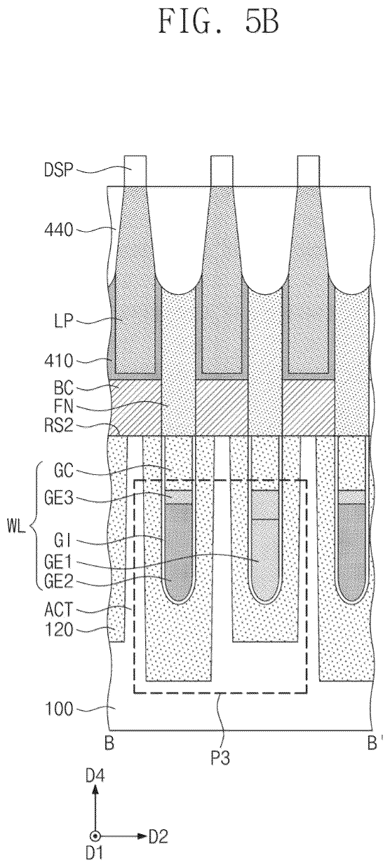

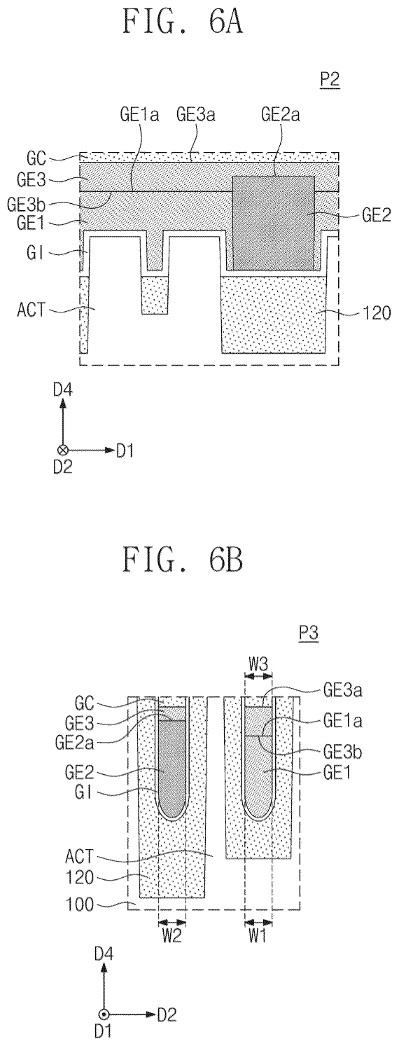

FIGS. 5A and 5B are sectional views, which are respectively taken along the lines A-A′ and B-B′ of FIG. 2 to illustrate a semiconductor memory device according to an embodiment. FIG. 6A is an enlarged sectional view corresponding to a portion ‘P2’ of FIG. 5A, and FIG. 6B is an enlarged sectional view corresponding to a portion ‘P3’ of FIG. 5B. Hereinafter, a semiconductor memory device according to an embodiment will be described with reference to FIGS. 5A to 6B. For concise description, a previously-described element may be identified by the same reference number without repeating an overlapping description thereof.

Referring to FIGS. 5A to 6B, the top surface GE2a of the second gate electrode GE2 may be located at a level higher than the top surface GE1a of the first gate electrode GE1. The top surface GE2a of the second gate electrode GE2 may be located at a level lower than the top surface GE3a of the third gate electrode GE3.

The third gate electrode GE3 may be provided on the second gate electrode GE2. As an example, the third gate electrode GE3 may cover the top surface GE2a of the second gate electrode GE2. The third gate electrode GE3 may cover a portion of a side surface of the second gate electrode GE2. In an embodiment, the side surface of the second gate electrode GE2 may be a surface facing the first direction D1.

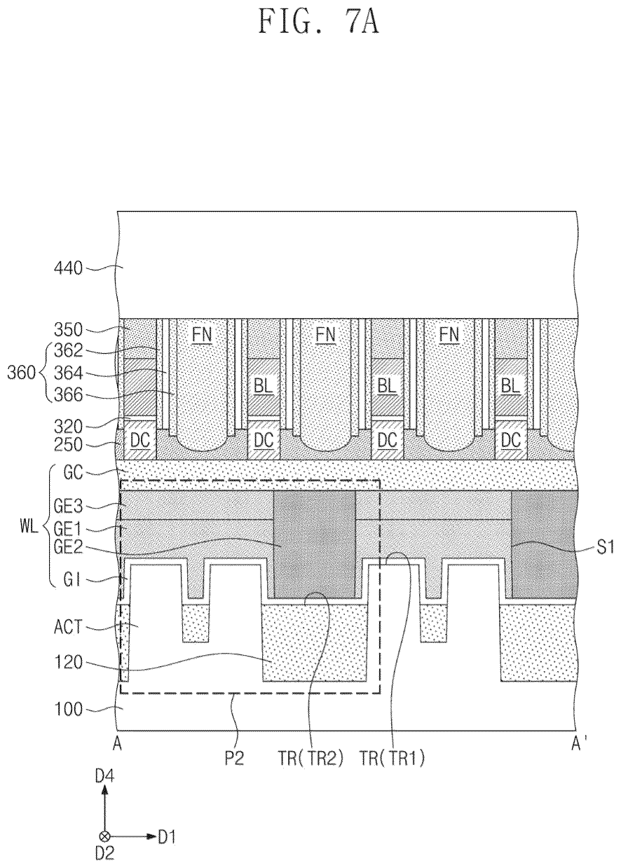

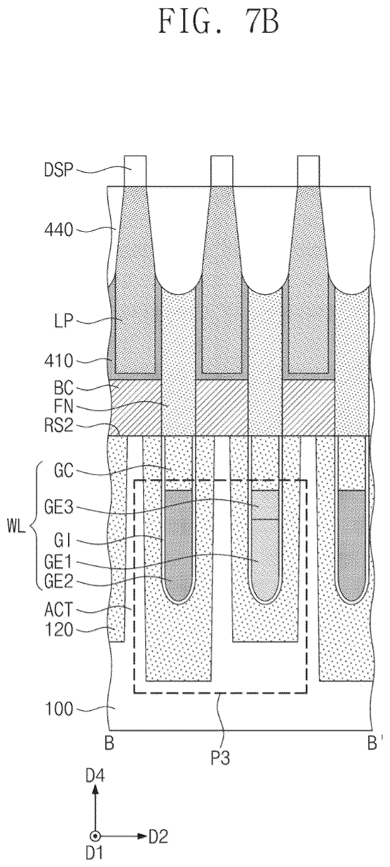

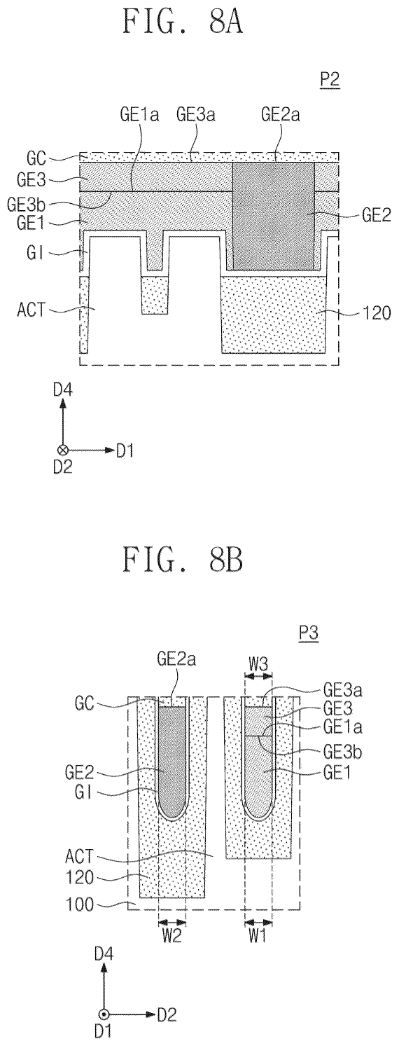

FIGS. 7A and 7B are sectional views, which are respectively taken along the lines A-A′ and B-B′ of FIG. 2 to illustrate a semiconductor memory device according to an embodiment. FIG. 8A is an enlarged sectional view corresponding to a portion ‘P2’ of FIG. 7A, and FIG. 8B is an enlarged sectional view corresponding to a portion ‘P3’ of FIG. 7B. Hereinafter, a semiconductor memory device according to an embodiment will be described with reference to FIGS. 7A to 8B. For concise description, a previously-described element may be identified by the same reference number without repeating an overlapping description thereof.

Referring to FIGS. 7A to 8B, the top surface GE2a of the second gate electrode GE2 may be located at substantially the same level as the top surface GE3a of the third gate electrode GE3. The top surface GE2a of the second gate electrode GE2 may be in contact with the gate capping pattern GC. In an embodiment, the top surfaces GE2a and GE3a of the second and third gate electrodes GE2 and GE3 may be in contact with a bottom surface of the gate capping pattern GC at the same level.

The second gate electrode GE2 may be placed on a side surface of each of the first and third gate electrodes GE1 and GE3. The second gate electrode GE2 may cover the side surface (e.g., the first side surface S1) of the first gate electrode GE1, which is substantially perpendicular to the first direction D1, and may be extended to the side surface of the third gate electrode GE3.

The third gate electrode GE3 may include a plurality of third gate electrodes GE3, which are adjacent to each other in the first direction D1. In an embodiment, the third gate electrode GE3 may be interposed between the second gate electrodes GE2, which are adjacent to each other in the first direction D1. The adjacent ones of the second gate electrodes GE2 and the adjacent ones of the third gate electrodes GE3 may be alternately disposed in the first direction D1.

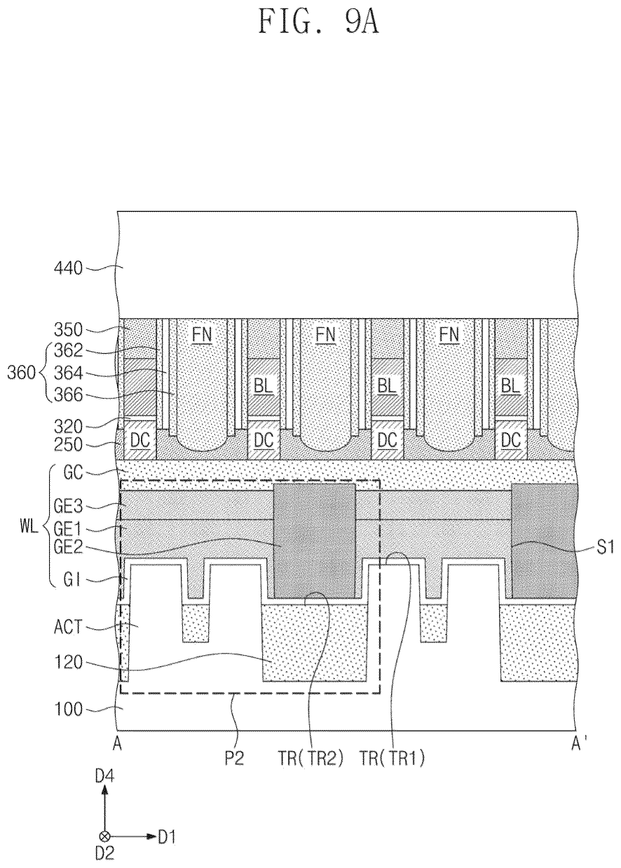

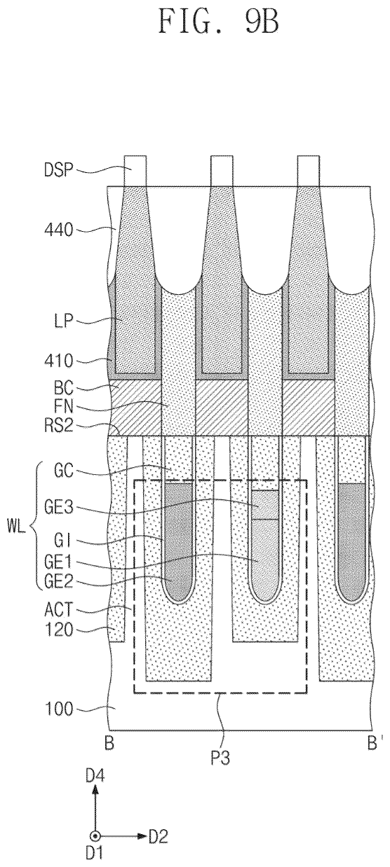

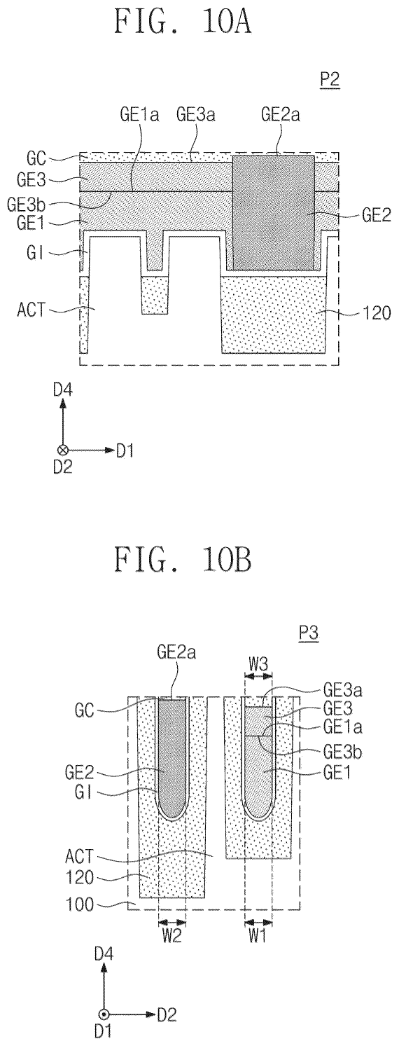

FIGS. 9A and 9B are sectional views, which are respectively taken along the lines A-A′ and B-B′ of FIG. 2 to illustrate a semiconductor memory device according to an embodiment. FIG. 10A is an enlarged sectional view corresponding to a portion ‘P2’ of FIG. 9A, and FIG. 10B is an enlarged sectional view corresponding to a portion ‘P3’ of FIG. 9B. Hereinafter, a semiconductor memory device according to an embodiment will be described with reference to FIGS. 9A to 10B. For concise description, a previously-described element may be identified by the same reference number without repeating an overlapping description thereof.

Referring to FIGS. 9A to 10B, the top surface GE2a of the second gate electrode GE2 may be located at a level higher than the top surface GE3a of the third gate electrode GE3. The top surface GE2a of the second gate electrode GE2 may be in contact with the gate capping pattern GC. In an embodiment, the top surface GE2a of the second gate electrode GE2 may be in contact with the gate capping pattern GC, at a level higher than the top surface GE3a of the third gate electrode GE3. The second gate electrode GE2 may be provided to penetrate the third gate electrode GE3.

The gate capping pattern GC may be placed on the second gate electrode GE2. As an example, the gate capping pattern GC may cover the top surface GE2a of the second gate electrode GE2. The gate capping pattern GC may cover a portion of a side surface of the second gate electrode GE2. In an embodiment, the side surface of the second gate electrode GE2 may be substantially perpendicular to the first direction D1.

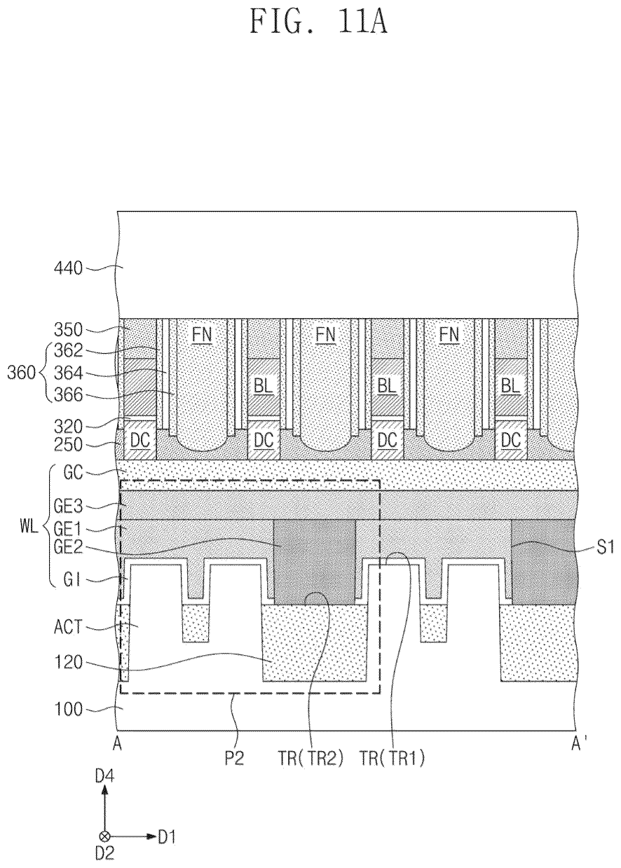

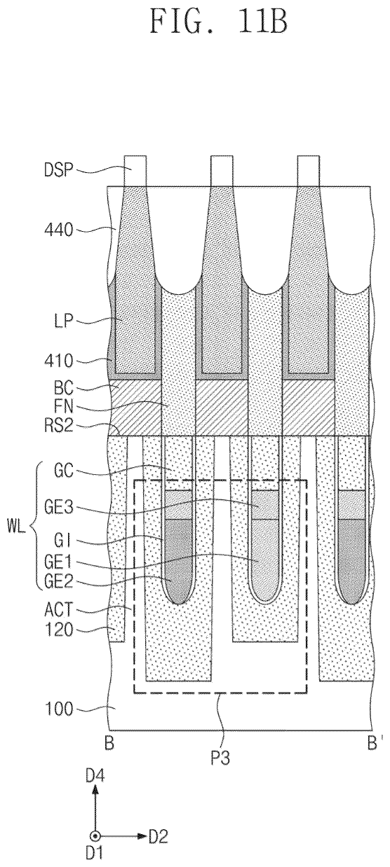

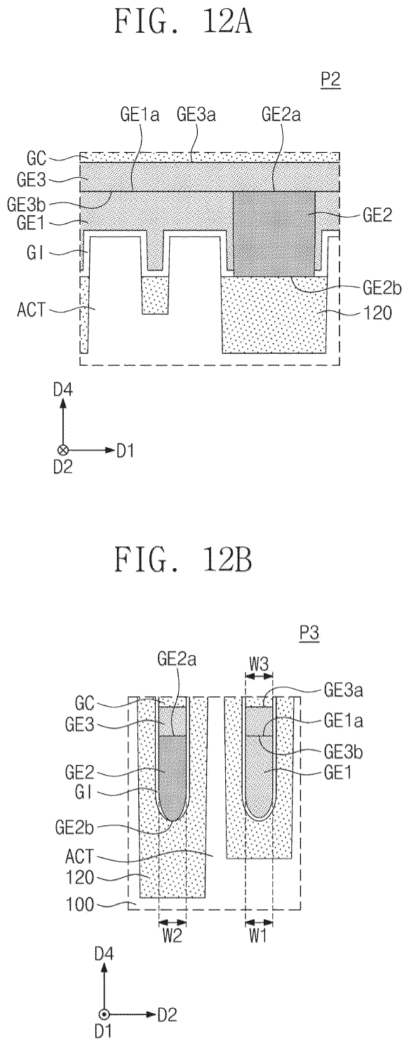

FIGS. 11A and 11B are sectional views, which are respectively taken along the lines A-A′ and B-B′ of FIG. 2 to illustrate a semiconductor memory device according to an embodiment. FIG. 12A is an enlarged sectional view corresponding to a portion ‘P2’ of FIG. 11A, and FIG. 12B is an enlarged sectional view corresponding to a portion ‘P3’ of FIG. 11B. Hereinafter, a semiconductor memory device according to an embodiment will be described with reference to FIGS. 11A to 12B. For concise description, a previously-described element may be identified by the same reference number without repeating an overlapping description thereof.

Referring to FIGS. 11A to 12B, a bottom surface GE2b of the second gate electrode GE2 may be in contact with the device isolation pattern 120. As an example, the bottom surface GE2b of the second gate electrode GE2 may be in contact with the device isolation pattern 120 filling the second trench region TR2. The second gate electrode GE2 may be provided to penetrate the gate insulating pattern GI, which is provided to conformally cover the second trench region TR2.

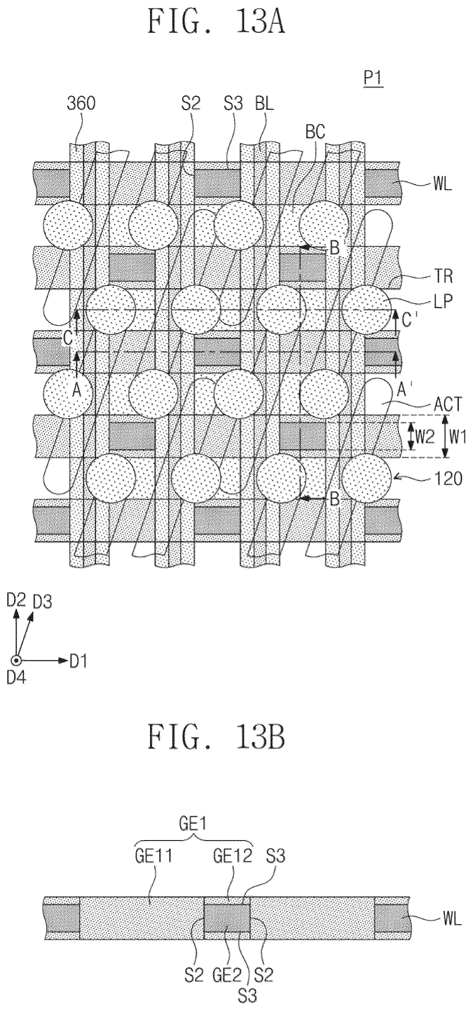

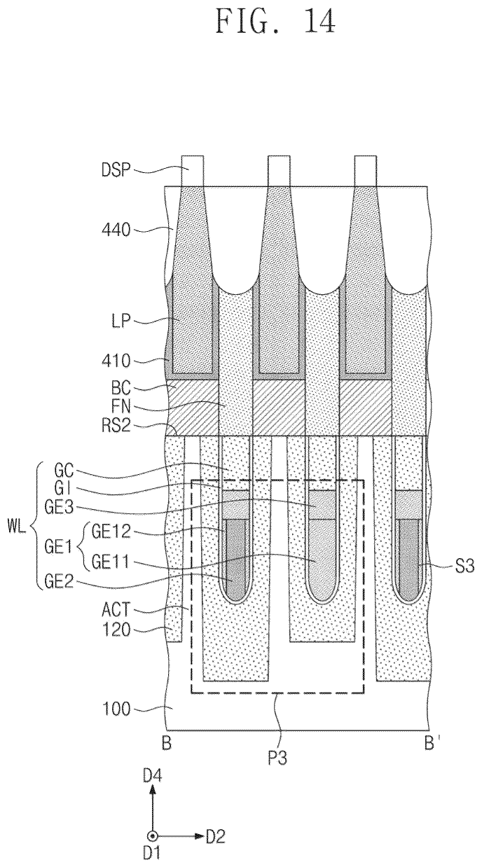

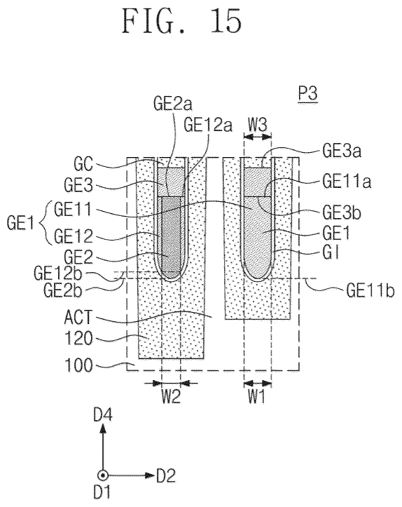

FIG. 13A is a plan view illustrating a semiconductor memory device according to an embodiment and corresponding to the portion ‘P1’ of FIG. 1. FIG. 13B is an enlarged sectional view corresponding to a word line of FIG. 13A. FIG. 14 is a sectional view taken along a line B-B′ of FIG. 13A to illustrate a semiconductor memory device according to an embodiment. FIG. 15 is an enlarged sectional view corresponding to a portion ‘P3’ of FIG. 14. Hereinafter, a semiconductor memory device according to an embodiment will be described with reference to FIGS. 13A to 15. For concise description, a previously-described element may be identified by the same reference number without repeating an overlapping description thereof.

Referring to FIGS. 13A to 15, the first gate electrode GE1 may be extended in the first direction D1 to cross the active pattern ACT and the device isolation pattern 120. The second gate electrode GE2 may be provided to penetrate the first gate electrode GE1. The second gate electrode GE2 may include a second side surface S2 and a third side surface S3. The second side surface S2 may be a side surface of the second gate electrode GE2, which is substantially perpendicular to the first direction D1. The third side surface S3 may be a side surface of the second gate electrode GE2, which is substantially perpendicular to the second direction D2.

The first and second gate electrodes GE1 and GE2 may include the top surfaces GE1a and GE2a, respectively. In an embodiment, the top surfaces GE1a and GE2a of the first and second gate electrodes GE1 and GE2 may be located at substantially the same level.

The first gate electrode GE1 may include a first region GE11 and a second region GE12, which are connected to each other in the first direction D1. The first region GE11 may be placed on one side surface (e.g., the second side surface S2) of the second gate electrode GE2. As an example, the first region GE11 may cover the second side surface S2 of the second gate electrode GE2. The second region GE12 may be placed on other side surface (e.g., the third side surface S3) of the second gate electrode GE2. As an example, the second region GE12 may cover the third side surface S3 of the second gate electrode GE2. The second gate electrode GE2 may be spaced apart from the device isolation pattern 120 by the first gate electrode GE1. The second gate electrode GE2 may be spaced apart from the device isolation pattern 120 by the second region GE12 of the first gate electrode GE1.

The first region GE11 may include a plurality of first regions GE11, which are adjacent to each other in the first direction D1. The second gate electrode GE2 may be interposed between the adjacent ones of the first regions GE11. As an example, the second region GE12 may be interposed between the adjacent ones of the first regions GE11. The second region GE12 may include a pair of second regions GE12, which are adjacent to each other in the second direction D2. The pair of the second regions GE12 may be spaced apart from each other with the second gate electrode GE2 interposed therebetween. The pair of the second regions GE12 may be interposed between the adjacent ones of the first regions GE11 and may connect them to each other.

The first and second regions GE11 and GE12 may include top surfaces GE11a and GE12a, respectively. In an embodiment, the top surfaces GE11a, GE12a, and GE2a of the first region GE11, the second region GE12, and the second gate electrode GE2 may be located at substantially the same level.

Each of the first and second regions GE11 and GE12 may include a bottom surface. The bottom surface GE2b of the second gate electrode GE2 may be located at a level, which is substantially equal to or lower than a bottom surface GE11b of the first region GE11. In an embodiment, the bottom surface GE2b of the second gate electrode GE2 may be located at a level lower than a bottom surface GE12b of the second region GE12.

The third gate electrode GE3 may be placed on the first and second gate electrodes GE1 and GE2. The third gate electrode GE3 may be placed on the first and second regions GE11 and GE12 of the first gate electrode GE1. In an embodiment, the third gate electrode GE3 may cover the top surfaces GE11a and GE12a of the first and second regions GE11 and GE12 and may be extended to the top surface of the second gate electrode GE2. In an embodiment, a blocking layer may be provided between two electrodes which are selected from the first, second, and third gate electrodes GE1, GE2, and GE3. The blocking layer may be a single layer or a composite layer.

The first width W1 of the top surface GE1a of the first gate electrode GE1 in the second direction D2 may be larger than the second width W2 of the top surface GE2a of the second gate electrode GE2 in the second direction D2. The second width W2 of the top surface GE2a of the second gate electrode GE2 in the second direction D2 may be smaller than the third width W3 of the top surface GE3a of the third gate electrode GE3 in the second direction D2. A width of the top surface of the second region GE12 of the first gate electrode GE1 in the first direction D1 may be substantially equal to a width of the top surface GE2a of the second gate electrode GE2 in the first direction D1.

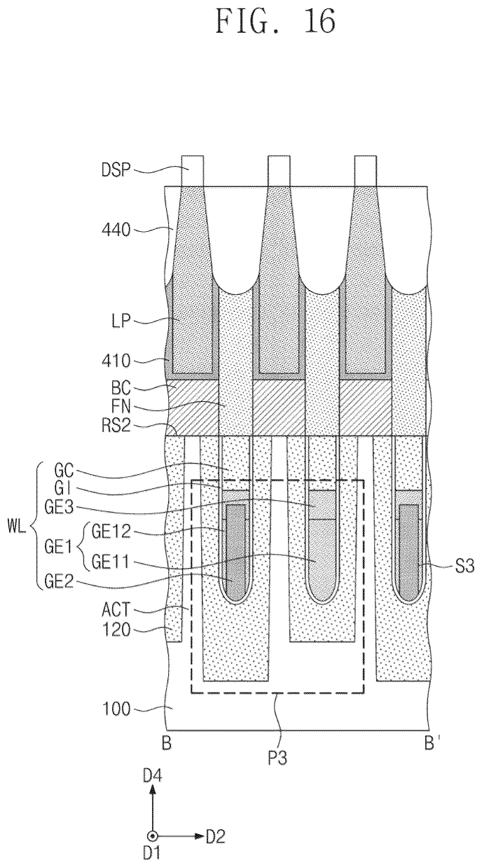

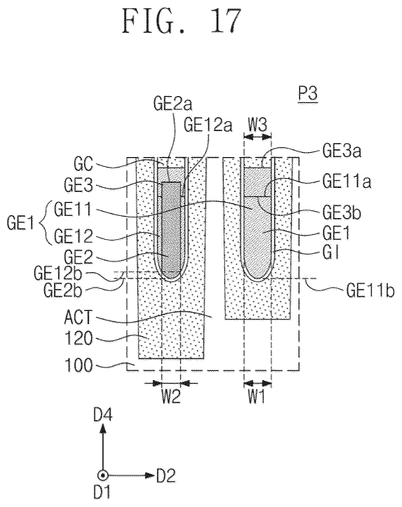

FIG. 16 is a sectional view taken along the line B-B′ of FIG. 13A to illustrate a semiconductor memory device according to an embodiment. FIG. 17 is an enlarged sectional view corresponding to a portion ‘P3’ of FIG. 16. Hereinafter, a semiconductor memory device according to an embodiment will be described with reference to FIGS. 16 and 17. For concise description, a previously-described element may be identified by the same reference number without repeating an overlapping description thereof.

Referring to FIGS. 16 and 17, the top surfaces GE11a and GE12a of the first and second regions GE11 and GE12 of the first gate electrode GE1 may be located at a level lower than the top surface GE2a of the second gate electrode GE2. The top surface GE2a of the second gate electrode GE2 may be in contact with the third gate electrode GE3. The top surface GE2a of the second gate electrode GE2 may be located at a level lower than the top surface GE3a of the third gate electrode GE3.

The third gate electrode GE3 may be provided on the second gate electrode GE2. As an example, the third gate electrode GE3 may cover the top surface GE2a of the second gate electrode GE2. The third gate electrode GE3 may enclose a side surface of an upper portion of the second gate electrode GE2.

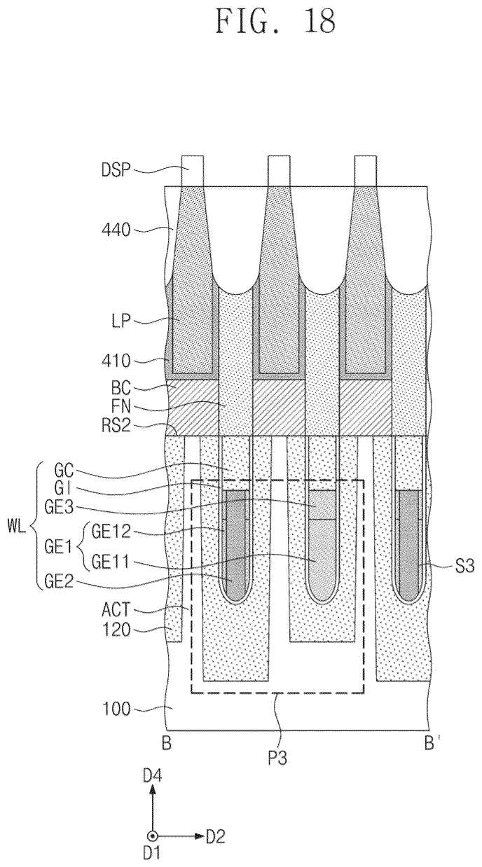

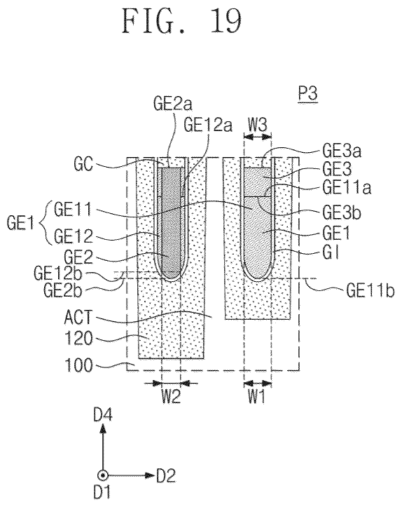

FIG. 18 is a sectional view taken along the line B-B′ of FIG. 13A to illustrate a semiconductor memory device according to an embodiment. FIG. 19 is an enlarged sectional view corresponding to a portion ‘P3’ of FIG. 18. Hereinafter, a semiconductor memory device according to an embodiment will be described with reference to FIGS. 18 and 19. For concise description, a previously-described element may be identified by the same reference number without repeating an overlapping description thereof.

Referring to FIGS. 18 and 19, the top surface GE2a of the second gate electrode GE2 may be located at substantially the same level as the top surface GE3a of the third gate electrode GE3. The top surface GE2a of the second gate electrode GE2 may be in contact with the gate capping pattern GC. In an embodiment, the top surfaces GE2a and GE3a of the second and third gate electrodes GE2 and GE3 may be in contact with the bottom surface of the gate capping pattern GC at substantially the same level.

The second gate electrode GE2 may be provided to penetrate the third gate electrode GE3. As an example, the second gate electrode GE2 may be extended from the first gate electrode GE1 into the third gate electrode GE3 and may penetrate the top surface GE3a of the third gate electrode GE3. An upper portion of the second gate electrode GE2 may be enclosed by the third gate electrode GE3. In an embodiment, the third gate electrode GE3 may include an inner side surface, and the upper portion of the second gate electrode GE2 may be enclosed by the inner side surface of the third gate electrode GE3. The second gate electrodes GE2, which are adjacent to each other in the first direction D1, may be spaced apart from each other by the third gate electrode GE3.

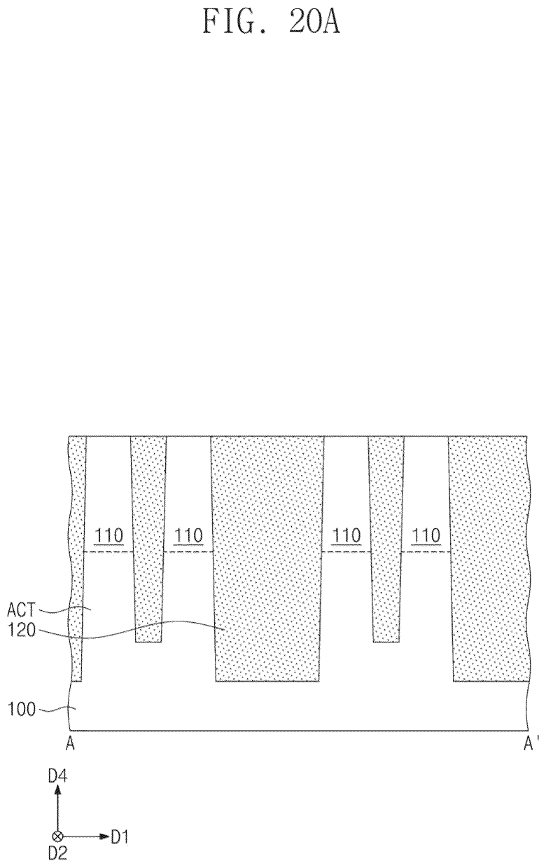

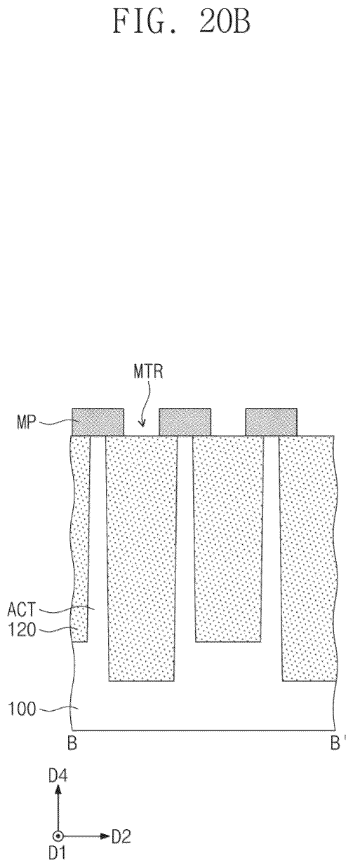

FIGS. 20A to 25B are sectional views illustrating a method of fabricating a semiconductor memory device, according to an embodiment. In detail, FIGS. 20A, 21A, 22A, 23A, 24A, and 25A are sectional views corresponding to the line A-A′ of FIG. 2. FIGS. 20B, 21B, 22B, 23B, 24B, and 25B are sectional views corresponding to the line B-B′ of FIG. 2. Hereinafter, a semiconductor fabricating method according to an embodiment will be described with reference to FIGS. 20A to 25B. For concise description, a previously-described element may be identified by the same reference number without repeating an overlapping description thereof.

Referring to FIGS. 2, 20A, and 20B, the substrate 100 may be prepared. The device isolation pattern 120, which is buried in an upper portion of the substrate 100, may be formed. The formation of the device isolation pattern 120 may include patterning the upper portion of the substrate 100 to form an isolation trench and forming the device isolation pattern 120 to fill the isolation trench. Remaining portions of the upper portion of the substrate 100, which are enclosed by the device isolation pattern 120, may be defined as the active patterns ACT. Impurity regions may be formed in the active patterns ACT. The formation of the impurity regions may include injecting impurities into the active patterns ACT through an ion implantation process.

A mask pattern MP may be formed on the active patterns ACT and the device isolation pattern 120. The mask pattern MP may include line-shaped patterns, which are extended in the first direction D1 and are spaced apart from each other in the second direction D2. When viewed in a plan view, the mask pattern MP may cross the active patterns ACT and the device isolation pattern 120 in the first direction D1. Mask trenches MTR may be formed between the line-shaped patterns of the mask pattern MP. The mask trenches MTR may be extended in the first direction D1 and may be spaced apart from each other in the second direction D2.

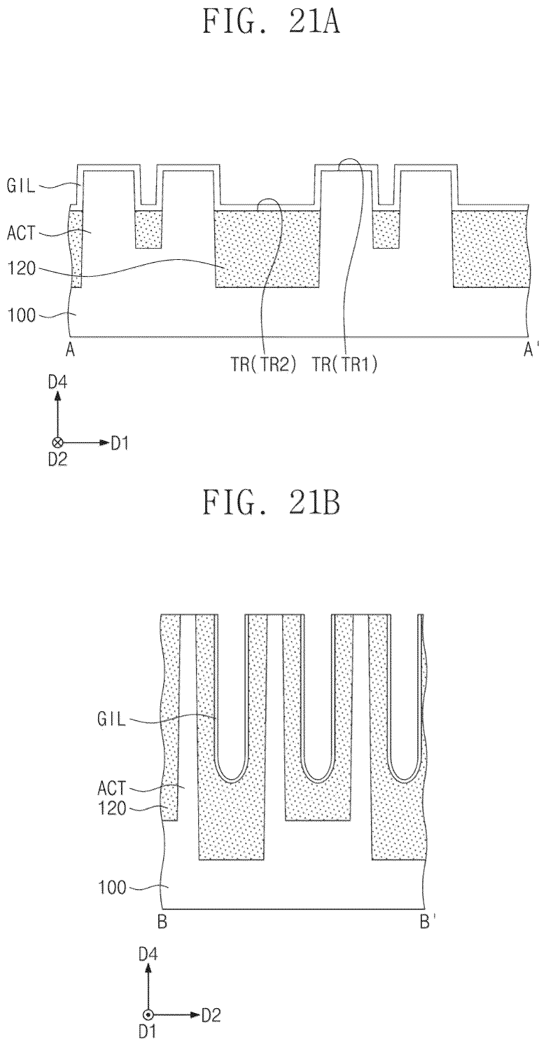

Referring to FIGS. 2, 21A, and 21B, upper portions of the active patterns ACT and an upper portion of the device isolation pattern 120 may be etched using the mask pattern MP as an etch mask. Thus, the trench regions TR may be formed to be vertically overlapped with the mask trenches MTR of the mask pattern MP. The trench regions TR may be extended in the first direction D1 and may be spaced apart from each other in the second direction D2. In an embodiment, a pair of the trench regions TR, which are adjacent to each other in the second direction D2, may cross each of the active patterns ACT in the first direction D1.

A bottom surface of each of the trench regions TR may be formed to have a non-flat shape. In an embodiment, the trench region TR may include the first trench region TR1 on the active pattern ACT and the second trench region TR2 on the device isolation pattern 120. A bottom surface of the first trench region TR1 may be formed at a level higher than a bottom surface of the second trench region TR2. Etch rates of the active pattern ACT and the device isolation pattern 120 may be different from each other, when the etching process is performed, and thus, the bottom surfaces of the first and second trench regions TR1 and TR2 may be formed at different levels. As a result, the bottom surface of each of the trench regions TR may have the non-flat shape.

Each of the active patterns ACT may include a pair of edge portions 111 and a center portion 112, which are delimited by the trench regions TR. The paired edge portions 111 may be defined at opposite edges of each of the active patterns ACT. The center portion 112 may be defined between the paired trench regions TR.

A gate insulating layer GIL may be conformally formed on the substrate 100. For example, the gate insulating layer GIL may conformally cover inner surfaces of the trench regions TR and may be extended to cover top surfaces of the active patterns ACT and a top surface of the device isolation pattern 120. A bottom surface of the gate insulating layer GIL may have a non-flat shape, due to the shape of the trench region TR. The gate insulating layer GIL may be formed using a physical vapor deposition (PVD) process, a chemical vapor deposition (CVD) process, or an atomic layer deposition (ALD) process. The gate insulating layer GIL may be formed of or include at least one of silicon oxide or various high-k dielectric materials.

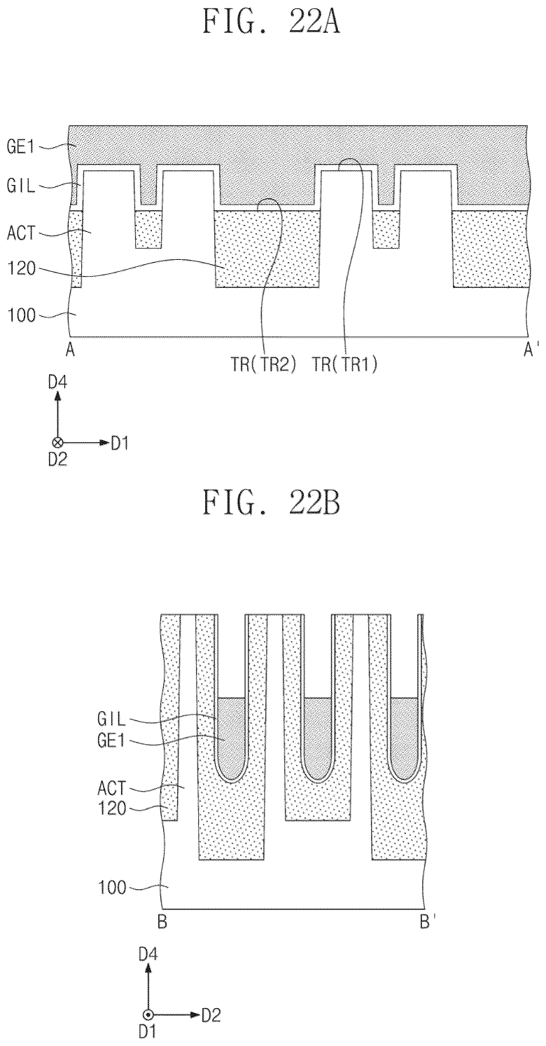

Referring to FIGS. 2, 22A, and 22B, the first gate electrode GE1 may be formed in the trench region TR. In an embodiment, the first gate electrode GE1 may be formed in a lower portion of the trench region TR. The formation of the first gate electrode GE1 may include forming a first gate electrode layer to fill the trench regions TR and cover the gate insulating layer GIL and removing an upper portion of the first gate electrode layer to form the first gate electrodes GE1, which are separated from each other. The formation of the first gate electrode layer may include performing a physical vapor deposition (PVD) process, a chemical vapor deposition (CVD) process, or an atomic layer deposition (ALD) process. The removal of the upper portion of the first gate electrode layer may include performing an etch-back process or a chemical mechanical planarization (CMP) process on the first gate electrode layer. Thus, the first gate electrode GE1 may fill a lower portion of the trench region TR. As a result of the removal of the upper portion of the first gate electrode layer, an upper portion of the gate insulating layer GIL may be exposed to the outside.

The first gate electrode GE1 may be extended along the trench region TR and in the first direction D1. A bottom surface of the first gate electrode GE1 may have an uneven shape, which is defined by a bottom surface of the trench region TR. In an embodiment, the top surface GE1a of the first gate electrode GE1 may be flat.

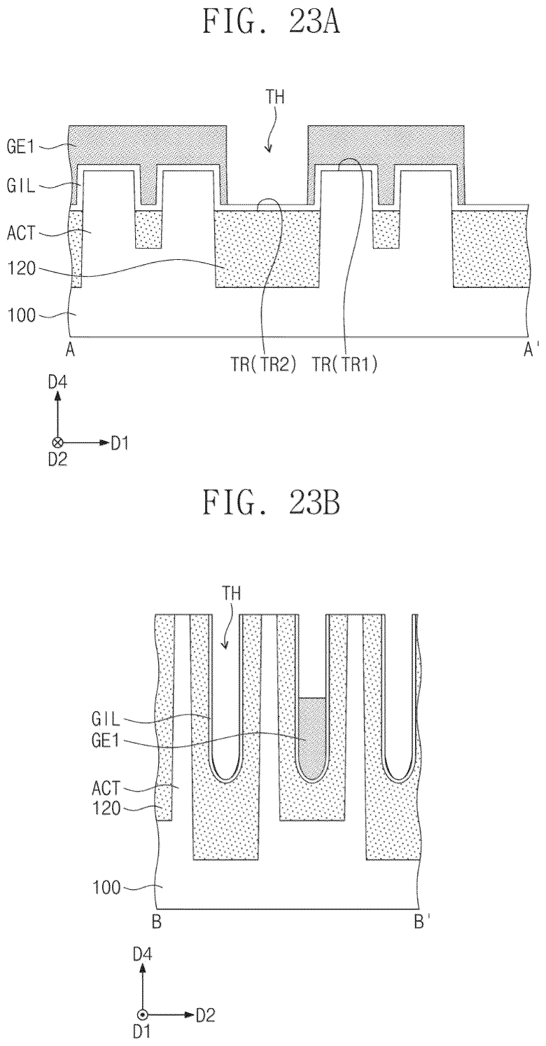

Referring to FIGS. 2, 23A, and 23B, a portion of the first gate electrode GE1 on the second trench region TR2 may be removed. Thus, a hole TH may be formed in the second trench region TR2. As an example, the first gate electrode GE1 in one trench region TR may be divided into a plurality of first gate electrodes GE1, which are separated from each other in the first direction D1, by the hole TH. The formation of the hole TH may include forming a first mask pattern with openings on the first gate electrode GE1 and etching a portion of the first gate electrode GE1 using the first mask pattern as an etch mask.

The first mask pattern may be formed on the substrate 100. The openings may be formed on the second trench regions TR2, respectively. The openings may be formed to be spaced apart from each other in the first and second directions D1 and D2. As an example, the openings on each trench region TR may be formed to be arranged in the first direction D1. The openings may include openings, which are arranged in the second direction D2, and each of which is formed on a corresponding one of the trench regions TR. When viewed in a plan view, the opening may be formed between the active patterns ACT, which are adjacent to each other in the third direction D3. When viewed in a plan view, the opening may be formed between four active patterns ACT, which are disposed in a clockwise direction.

A portion of the first gate electrode GE1 may be etched using the first mask pattern with the opening as an etch mask. The opening may be vertically overlapped with the etched portion of the first gate electrode GE1. Thus, the opening may be formed to be vertically overlapped with the hole TH.

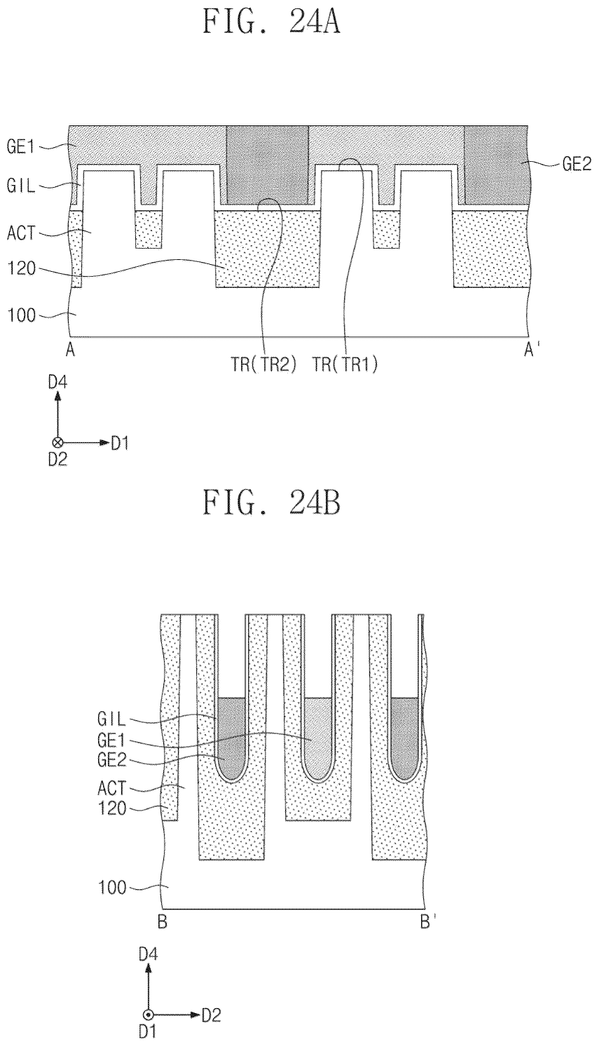

Referring to FIGS. 2, 24A, and 24B, the second gate electrode GE2 may be formed in the hole TH. The formation of the second gate electrode GE2 may include forming a second gate electrode layer to fill the hole TH and cover the top surface GE1a of the first gate electrode GE1 and removing an upper portion of the second gate electrode layer to form the second gate electrodes GE2, which are separated from each other.

In detail, the formation of the second gate electrode layer may include performing a chemical vapor deposition (CVD) process or an atomic layer deposition (ALD) process. In an embodiment, each of the CVD and ALD processes may be performed in a selective deposition manner. The selective deposition may refer to a deposition method that can deposit a target material on only desired materials, while preventing or suppressing the target material from being deposited on undesired materials. As a result of the selective deposition, the second gate electrode layer may be selectively formed on the top surface GE1a of the first gate electrode GE1 and in the hole TH. The removal of the upper portion of the second gate electrode layer may include performing an etch-back process on the second gate electrode layer. Thus, the second gate electrode GE2 may be left in the hole TH. As a result of the removal of the upper portion of the second gate electrode layer, an upper portion of the gate insulating layer GIL may be exposed to the outside. In an embodiment, an upper portion of the first gate electrode GE1 may be further removed. The first gate electrode GE1 and the second gate electrode GE2 may be formed to have the top surface GE1a and the top surface GE2a, which are located at substantially the same level and are coplanar with each other.

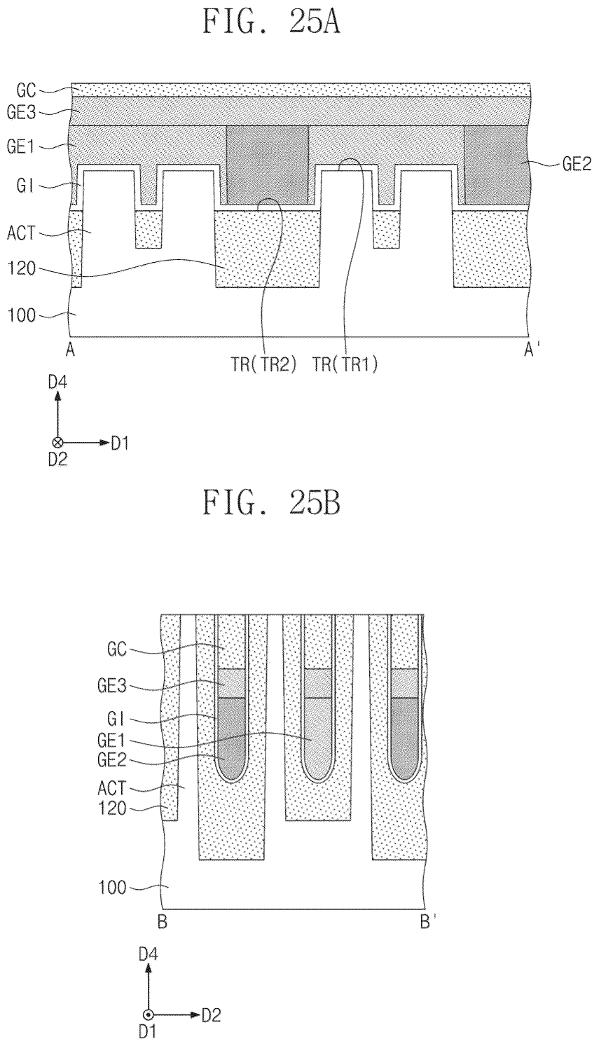

Referring to FIGS. 2, 25A, and 25B, the third gate electrode GE3 may be formed in the trench region TR. In an embodiment, the third gate electrode GE3 may partially fill the trench region TR. The third gate electrode GE3 may be formed to extend in the first direction D1 and cross the trench region TR. The third gate electrode GE3 may be formed on the top surfaces GE1a and GE2a of the first and second gate electrodes GE1 and GE2. The third gate electrode GE3 may be formed to cover the top surface GE1a of the first gate electrode GE1 and may be extended in the first direction D1 to cover the top surface GE2a of the second gate electrode GE2. The formation of the third gate electrode GE3 may include forming a third gate electrode layer to fill the trench region TR and cover the entire top surface of the substrate 100 and removing an upper portion of the third gate electrode layer to form the third gate electrodes GE3, which are separated from each other. The formation of the third gate electrode layer may include performing a chemical vapor deposition (CVD) process or an atomic layer deposition (ALD) process. In an embodiment, the removal of the upper portion of the third gate electrode layer may include performing an etch-back process on the second gate electrode layer. Accordingly, the third gate electrode GE3 may fill a portion of the trench region TR. As a result of the removal of the upper portion of the third gate electrode layer, an upper portion of the gate insulating layer GIL may be exposed to the outside.

Thereafter, the gate capping pattern GC may be formed on the third gate electrode GE3. The gate capping pattern GC may fill remaining portions of the trench regions TR, respectively. The formation of the gate capping pattern GC may include forming a gate capping layer to fill a remaining portion of the trench region TR and cover the top surfaces of the active patterns ACT and the top surface of the device isolation pattern 120, and removing an upper portion of the gate capping layer to form the gate capping patterns GC which are separated from each other.

The gate insulating pattern GI may be formed by removing an upper portion of the gate insulating layer GIL. In detail, portions of the gate insulating layer GIL may be removed from the top surfaces of the active patterns ACT and the top surface of the device isolation pattern 120, and in this case, remaining portions of the gate insulating layer GIL may constitute the gate insulating patterns GI. The gate insulating pattern GI may conformally cover an inner surface of the trench region TR.

The first gate electrode GE1, the second gate electrode GE2, the third gate electrode GE3, the gate insulating pattern GI, and the gate capping pattern GC may constitute the word line WL.

Referring back to FIGS. 2 to 4B, a buffer layer and a poly-silicon layer may be formed to cover the active patterns ACT and the device isolation pattern 120, and the first recess region RS1 may be formed on each of the active patterns ACT and the device isolation pattern 120. Here, the buffer layer and the poly-silicon layer may be partially removed to form the buffer pattern 210 and the polysilicon pattern 310.

The bit line contact DC, the first ohmic pattern 320, the bit line BL, and the bit line capping pattern 350 may be formed on the first recess region RS1. The formation of the bit line contact DC, the first ohmic pattern 320, the bit line BL, and the bit line capping pattern 350 may include forming a bit line contact layer to fill the first recess region RS1, sequentially forming a first ohmic layer, a bit line layer, and a bit line capping layer on the bit line contact layer, and etching the bit line contact layer, the first ohmic layer, the bit line layer, and the bit line capping layer to form the bit line contact DC, the first ohmic pattern 320, the bit line BL, and the bit line capping pattern 350. Here, a portion of the polysilicon pattern 310 may be further etched. During this process, an inner portion of the first recess region RS1 may be partially re-exposed to the outside. Thereafter, the gapfill insulating pattern 250 may be formed to fill a remaining portion of the first recess region RS1. During the formation of the bit line BL, a first barrier pattern may be further formed between the bit line BL and the bit line contact DC and between the bit line BL and the polysilicon pattern 310.

The bit line spacer 360 may be formed to cover a side surface of the bit line BL and a side surface of the bit line capping pattern 350. The formation of the bit line spacer 360 may include sequentially forming the first spacer 362, the second spacer 364, and the third spacer 366 to conformally cover the side surface of the bit line BL and the bit line capping pattern 350.

The storage node contacts BC and the fence patterns FN may be formed between adjacent ones of the bit lines BL. The storage node contacts BC and the fence patterns FN may be alternately arranged in the second direction D2. Each of the storage node contacts BC may be formed to fill the second recess region RS2 and may be electrically connected to a corresponding edge portion 111 of the active pattern ACT in the second recess region RS2. The fence patterns FN may be formed at positions that are vertically overlapped with the word lines WL. In an embodiment, the storage node contacts BC may be formed first, and then the fence patterns FN may be formed between the storage node contacts BC. In another embodiment, the fence patterns FN may be formed first, and then the storage node contacts BC may be formed between the fence patterns FN.

An upper portion of the bit line spacer 360 may be partially removed during the formation of the storage node contacts BC. In this case, the capping spacer 370 may be additionally formed in a region, which is formed by removing the bit line spacer 360. Next, the second barrier pattern 410 may be formed to conformally cover the bit line spacer 360, the capping spacer 370, and the storage node contacts BC.

The landing pads LP may be formed on the storage node contacts BC. The formation of the landing pads LP may include sequentially forming a landing pad layer and mask patterns to cover top surfaces of the storage node contacts BC and dividing the landing pad layer into a plurality of landing pads LP through an anisotropic etching process using the mask patterns as an etch mask. Additionally, the second barrier pattern 410, the bit line spacer 360, and the bit line capping pattern 350 may be partially etched through an etching process and may be exposed to the outside. An upper portion of the landing pad LP may be shifted from the storage node contact BC in the first direction D1.

In an embodiment, the etching process on the landing pad layer may be performed to expose the second spacer 364. The second spacer 364 may be further etched through the exposed portion of the second spacer 364, and in this case, a final structure of the second spacer 364 may include an air gap. However, embodiments are not limited to this example.

Thereafter, the filler pattern 440 may be formed to cover the exposed portions and to enclose each of the landing pads LP, and the data storage patterns DSP may be formed on the landing pads LP, respectively.

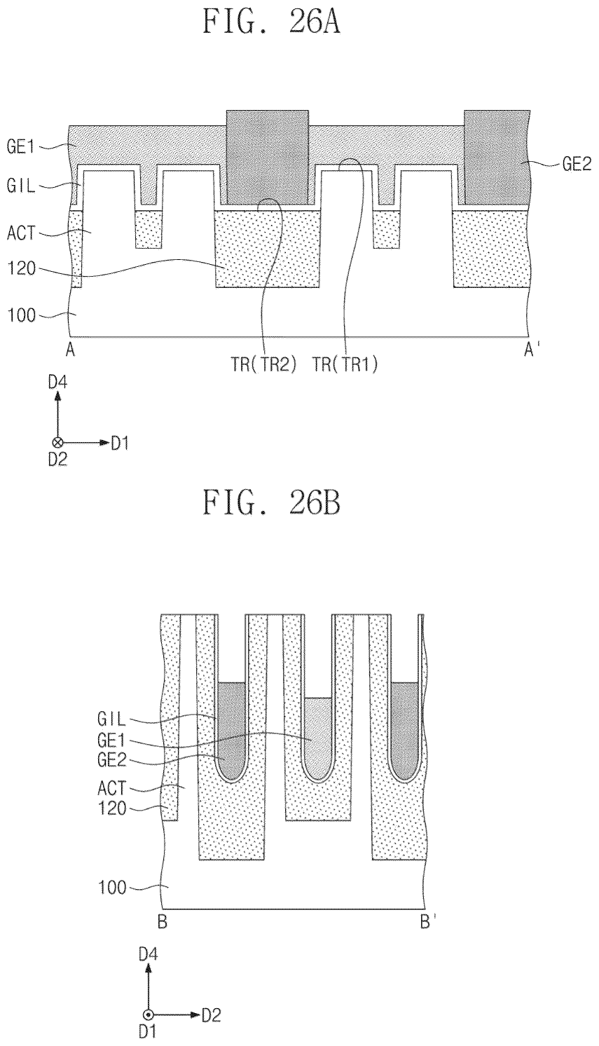

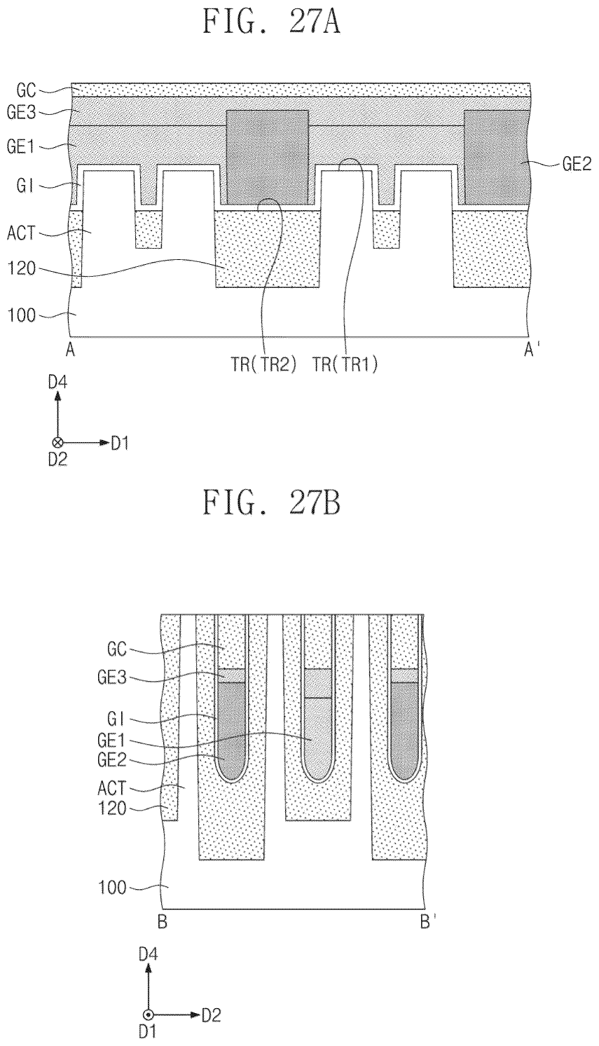

FIGS. 26A to 27B are sectional views illustrating a method of fabricating a semiconductor memory device, according to an embodiment. For concise description, a previously-described element may be identified by the same reference number without repeating an overlapping description thereof.

Referring to FIGS. 26A and 26B, after the etching process of the first gate electrode GE1 described with reference to FIGS. 23A and 23B, the second gate electrode GE2 may be formed in the hole TH. In an embodiment, the formation of the second gate electrode GE2 may be performed by a method similar to the one described with reference to FIGS. 24A and 24B.

In this process, the second gate electrode GE2 may be formed such that the top surface GE2a thereof is located at a level higher than the top surface GE1a of the first gate electrode GE1.

Thereafter, referring to FIGS. 27A and 27B, the third gate electrode GE3 may be located on each of the first and second gate electrodes GE1 and GE2. The formation of the third gate electrode GE3 may be performed by a method similar to the one described with reference to FIGS. 25A and 25B.

The gate capping pattern GC may be formed on the top surface GE3a of the third gate electrode GE3. The formation of the gate capping pattern GC may be performed by a method similar to the one described with reference to FIGS. 25A and 25B. Thereafter, a semiconductor memory device may be fabricated through a process that is similar to that described with reference to FIGS. 3A to 4B. Here, the fabricated semiconductor memory device may have substantially the same structure as the semiconductor memory device described with reference to FIGS. 5A to 6.

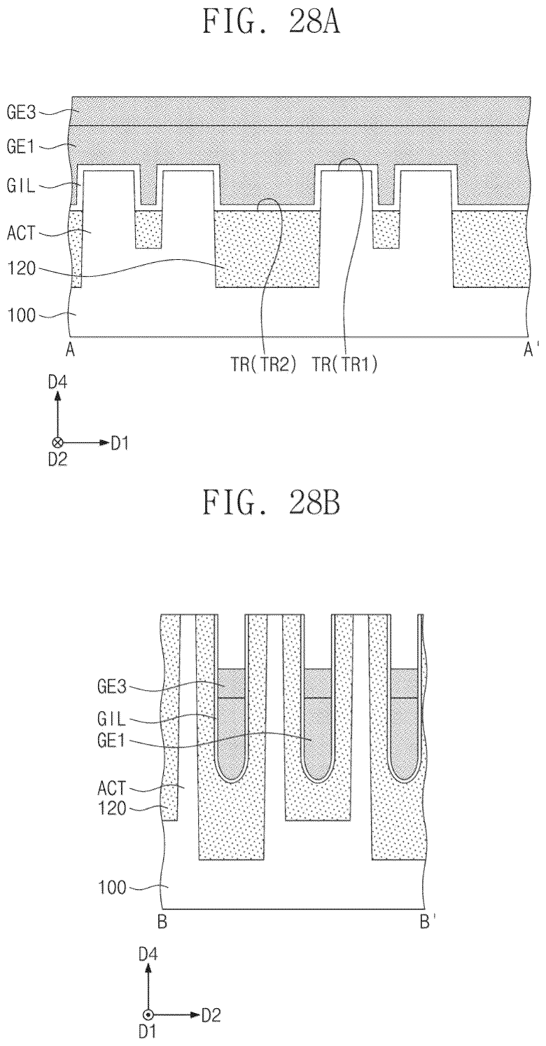

FIGS. 28A to 30B are sectional views illustrating a method of fabricating a semiconductor memory device, according to an embodiment. For concise description, a previously-described element may be identified by the same reference number without repeating an overlapping description thereof.

Referring to FIGS. 28A and 28B, after the formation of the first gate electrode GE1 described with reference to FIGS. 22A and 22B, the third gate electrode GE3 may be formed in the trench region TR. In an embodiment, the third gate electrode GE3 may partially fill the trench region TR. The third gate electrode GE3 may be formed to extend in the first direction D1 and cross the trench region TR. The third gate electrode GE3 may be formed on the top surface GE1a of the first gate electrode GE1. The third gate electrode GE3 may cover the top surface GE1a of the first gate electrode GE1. The formation of the third gate electrode GE3 may include forming a third gate electrode layer to fill the trench region TR and cover the gate insulating layer GIL and the top surface GE1a of the first gate electrode GE1 and etching an upper portion of the third gate electrode layer to form the third gate electrodes GE3, which are separated from each other. Accordingly, the third gate electrode GE3 may fill a portion of the trench region TR. An upper portion of the gate insulating layer GIL may be exposed to the outside by etching an upper portion of the third gate electrode layer.

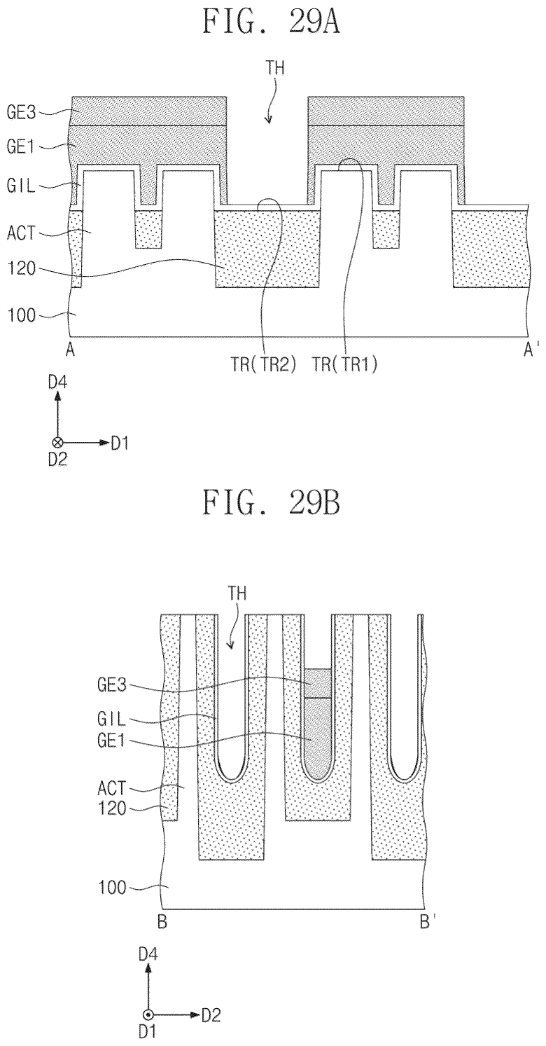

Referring to FIGS. 29A and 29B, the first and third gate electrodes GE1 and GE3 on the second trench region TR2 may be partially removed. Thus, the hole TH may be formed on the second trench region TR2. In an embodiment, the first gate electrodes GE1 and the third gate electrodes GE3 may be separated from each other by the hole TH. As an example, the formation of the hole TH on the second trench region TR2 may be performed by a method similar to the one described with reference to FIGS. 23A and 23B.

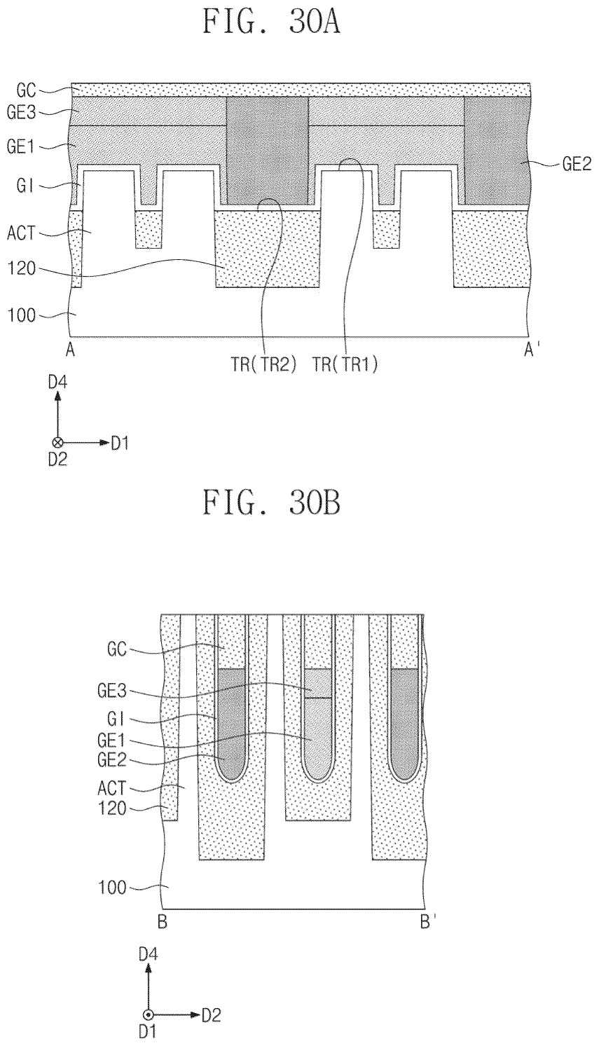

Referring to FIGS. 30A and 30B, the second gate electrode GE2 may be formed in the hole TH. As an example, the second gate electrode GE2 may be formed in a lower portion of the second trench region TR2. The formation of the second gate electrode GE2 may include forming a second gate electrode layer to fill the second trench region TR2 and cover the gate insulating layer GIL, a side surface of the first gate electrode GE1, and a side surface and the top surface GE3a of the third gate electrode GE3 and etching an upper portion of the second gate electrode layer to form the second gate electrodes GE2, which are separated from each other. Thus, the second gate electrode GE2 may fill the lower portion of the second trench region TR2.

In this process, the second gate electrode GE2 may be formed such that the top surface GE2a thereof is located at a level equal to or higher than the top surface GE3a of the third gate electrode GE3.

The third gate electrode GE3 may be interposed between the second gate electrodes GE2, which are adjacent to each other in the first direction D1. The first gate electrode GE1 may be interposed between the second gate electrodes GE2, which are adjacent to each other in the first direction D1. An upper portion of the gate insulating layer GIL may be exposed to the outside by etching an upper portion of the second gate electrode layer.

The gate capping pattern GC may be formed on each of the top surfaces GE2a and GE3a of the second and third gate electrodes GE2 and GE3. In an embodiment, the gate capping pattern GC may cover the top surface GE3a of the third gate electrode GE3 and may be extended in the first direction D1 to cover the top surface GE2a of the second gate electrode GE2. The formation of the gate capping pattern GC may be performed by a method similar to the one described with reference to FIGS. 25A and 25B. Thereafter, a semiconductor memory device may be fabricated through a process that is similar to the one described with reference to FIGS. 3A to 4B. Here, the fabricated semiconductor memory device may have substantially the same structure as the semiconductor memory device described with reference to FIGS. 7A to 10B.

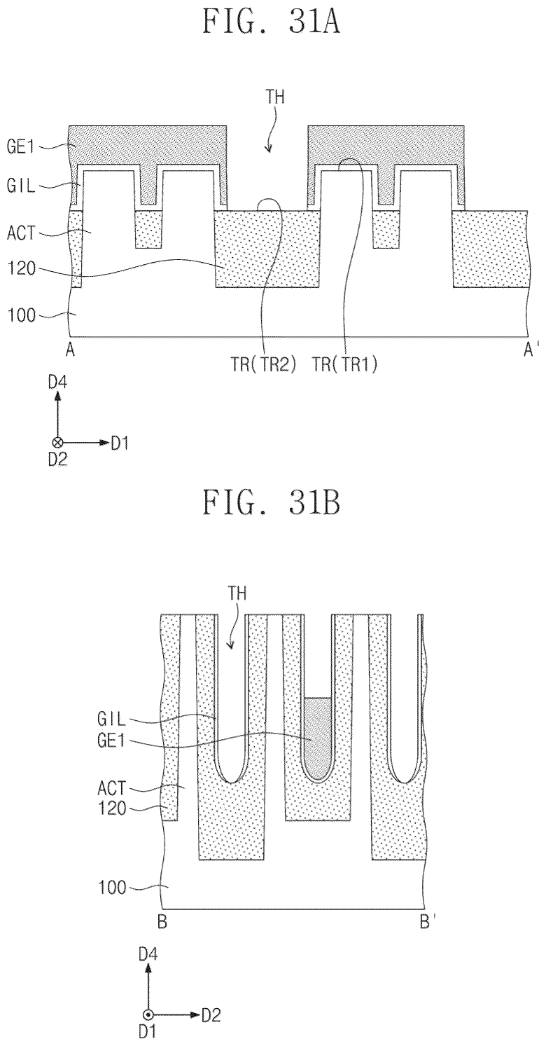

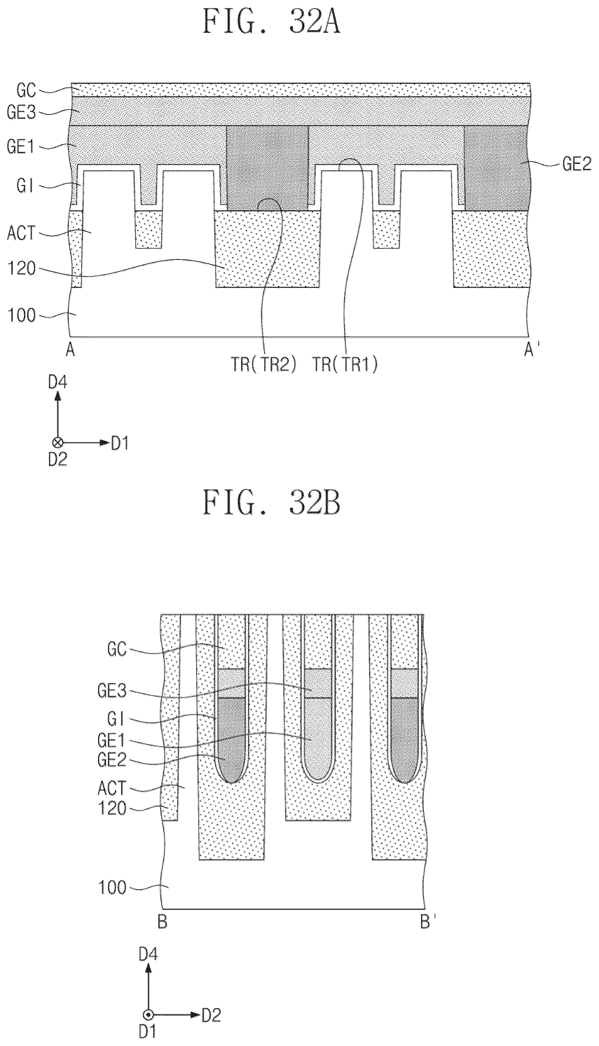

FIGS. 31A to 32B are sectional views illustrating a method of fabricating a semiconductor memory device, according to an embodiment. For concise description, a previously-described element may be identified by the same reference number without repeating an overlapping description thereof.

Referring to FIGS. 31A and 31B, after the etching process of the first gate electrode GE1 described with reference to FIGS. 23A and 23B, a portion of the gate insulating layer GIL may be further removed from the second trench region TR2. A portion of the device isolation pattern 120 may be exposed through the etching process. The removal of the first gate electrode GE1 may be performed by a method similar to that described with reference to FIGS. 23A and 23B.

Referring to FIGS. 32A and 32B, after the etching process of the first gate electrode GE1 described with reference to FIGS. 23A and 23B, the second gate electrode GE2 may be formed in the hole TH on the second trench region TR2. The formation of the second gate electrode GE2 may be performed by a method similar to the one described with reference to FIGS. 24A and 25B. As an example, a bottom surface of the second gate electrode GE2 may be in contact with the device isolation pattern 120 on the second trench region TR2. In an embodiment, the second gate electrode GE2 may be formed to penetrate the gate insulating layer GIL on the second trench region TR2.

Thereafter, the third gate electrode GE3 may be provided on the first and second gate electrodes GE1 and GE2. The formation of the third gate electrode GE3 may be performed by a method similar to the one described with reference to FIGS. 25A and 25B.

Next, the gate capping pattern GC may be formed on the top surface GE3a of the third gate electrode GE3. The formation of the gate capping pattern GC may be performed by a method similar to the one described with reference to FIGS. 25A and 25B. Thereafter, a semiconductor memory device may be fabricated through a process that is similar to the one described with reference to FIGS. 3A to 4B. Here, the fabricated semiconductor memory device may have substantially the same structure as the semiconductor memory device described with reference to FIGS. 11A to 12B.

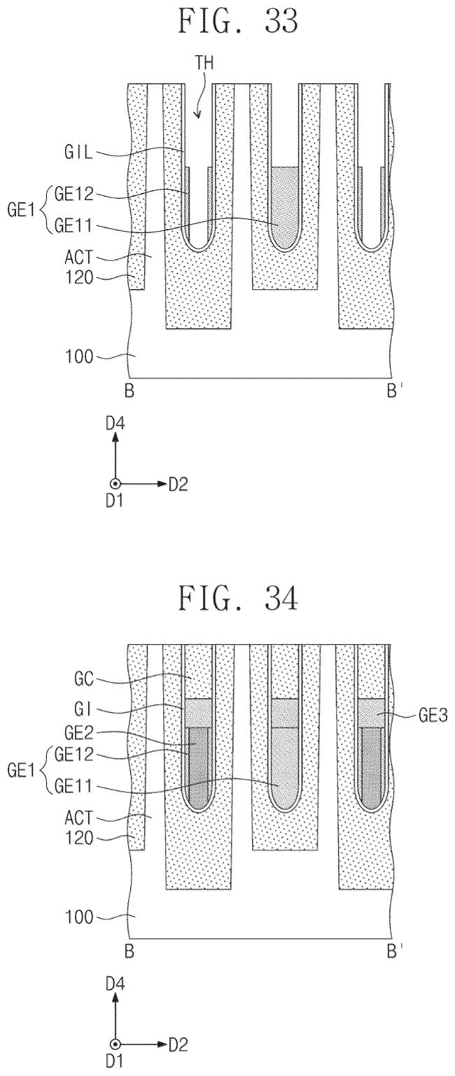

FIGS. 33 and 34 are sectional views illustrating a method of fabricating a semiconductor memory device, according to an embodiment. For concise description, a previously-described element may be identified by the same reference number without repeating an overlapping description thereof.

Referring to FIG. 33, after the etching process of the first gate electrode GE1 described with reference to FIGS. 23A and 23B, the hole TH may be formed on the second trench region TR2. In an embodiment, a plurality of holes TH may be formed on the second trench regions TR2. As an example, the holes TH may include a group of holes TH, which are arranged in the first direction D1. The first gate electrode GE1 may be divided into the first and second regions GE11 and GE12 by the hole TH. The first region GE11 may be a portion of the first gate electrode GE1 interposed between the group of the holes TH. As an example, the second region GE12 may be a portion of the first gate electrode GE1, which is provided in the second trench region TR2 and is interposed between the hole TH and the device isolation pattern 120. The second region GE12 may include a pair of the second regions GE12, which are adjacent to each other in the second direction D2. In an embodiment, the paired second regions GE12 may be spaced apart from each other by the hole TH.

Referring to FIG. 34, the second gate electrode GE2 may be formed in the hole TH on the second trench region TR2. The formation of the second gate electrode GE2 may include forming a second gate electrode layer to fill the second trench region TR2 and cover the gate insulating layer GIL and side and top surfaces of the first and second regions GE11 and GE12, after the formation of the first and second regions GE11 and GE12, and then, etching an upper portion of the second gate electrode layer to form the second gate electrodes GE2, which are separated from each other. Thus, the second gate electrode GE2 may fill the lower portion of the second trench region TR2.

The third gate electrode GE3 may be placed on the first and second gate electrodes GE1 and GE2. The formation of the third gate electrode GE3 may be performed by a method similar to the one described with reference to FIGS. 25A and 25B.

Next, the gate capping pattern GC may be formed on the top surface GE3a of the third gate electrode GE3. The formation of the gate capping pattern GC may be performed by a method similar to the one described with reference to FIGS. 25A and 25B. Thereafter, a semiconductor memory device may be fabricated through a process that is similar to the one described with reference to FIGS. 3A to 4B. Here, the fabricated semiconductor memory device may have substantially the same structure as the semiconductor memory device described with reference to FIGS. 13A to 19.

According to an embodiment, a word line may include a first gate electrode and a second gate electrode, which are adjacent to each other in a first direction parallel to a substrate. Here, the second gate electrode, which has a second work function, is provided on a side surface, in the first direction, of the first gate electrode, which has a first work function smaller than the second work function, and thus, it may be possible to improve the electrical and reliability characteristics of the semiconductor memory device.

While aspects of example embodiments have been particularly shown and described, it will be understood by one of ordinary skill in the art that variations in form and detail may be made therein without departing from the spirit and scope of the attached claims.

What is claimed is:

1. A semiconductor memory device, comprising:
an active pattern provided on a substrate and enclosed by a device isolation pattern; and
a word line crossing the active pattern and the device isolation pattern in a first direction parallel to a bottom surface of the substrate, and comprising a first gate electrode and a second gate electrode, which are adjacent to each other in the first direction,
wherein a second work function of the second gate electrode is greater than a first work function of the first gate electrode.

2. The semiconductor memory device of claim 1, wherein a first side surface of the first gate electrode faces the first direction, and
wherein the second gate electrode is on the first side surface of the first gate electrode.

3. The semiconductor memory device of claim 1, wherein the word line comprises a pair of word lines crossing the active pattern in the first direction, and
wherein the first gate electrode of a first one of the pair of word lines and the second gate electrode of a second one of the pair of word lines are adjacent to each other in a second direction crossing the first direction.

4. The semiconductor memory device of claim 1, wherein the word line is a first word line,
wherein the active pattern is a first active pattern,
wherein the semiconductor memory device further comprises:
a second word line, which is adjacent to the first word line in a second direction crossing the first direction; and
a second active pattern, which is adjacent to the first active pattern in a third direction crossing the first and second directions, and
wherein the second gate electrode of the second word line is interposed between the first active pattern and the second active pattern.

5. The semiconductor memory device of claim 1, wherein the first gate electrode comprises a plurality of first gate electrodes,
wherein the second gate electrode comprises a plurality of second gate electrodes, and
wherein the plurality of first gate electrodes and the plurality of second gate electrodes are alternately disposed in the first direction.

6. The semiconductor memory device of claim 1, wherein a top surface of the second gate electrode is located at a level, which is equal to or higher than a top surface of the first gate electrode along a vertical direction perpendicular to the bottom surface of the substrate.

7. The semiconductor memory device of claim 1, wherein a bottom surface of the second gate electrode is in contact with the device isolation pattern.

8. The semiconductor memory device of claim 1, wherein the first gate electrode and the second gate electrode comprise different materials, each of which comprises at least one of Ti, TiN, TiSiN, TiON, W, WN, Mo, MON, MoOₓN_{y}, Ta, TaN, or poly Si.

9. The semiconductor memory device of claim 1, wherein the second gate electrode has a resistivity smaller than the first gate electrode.

10. The semiconductor memory device of claim 1, further comprising a third gate electrode on the first gate electrode,
wherein a third work function of the third gate electrode is smaller than the first work function of the first gate electrode.

11. The semiconductor memory device of claim 10, wherein the third gate electrode extends from a top surface of the first gate electrode to a region on a top surface of the second gate electrode.

12. The semiconductor memory device of claim 10, wherein the second gate electrode comprises a plurality of second gate electrodes, which are adjacent to each other in the first direction, and
wherein the third gate electrode is interposed between adjacent ones of the plurality of second gate electrodes.

13. The semiconductor memory device of claim 10, wherein a top surface of the second gate electrode is located at a level, which is equal to or higher than a top surface of the third gate electrode along a vertical direction perpendicular to the bottom surface of the substrate.

14. A semiconductor memory device, comprising:
an active pattern provided on a substrate and enclosed by a device isolation pattern;
a first gate electrode crossing the active pattern and the device isolation pattern in a first direction parallel to a bottom surface of the substrate; and
a second gate electrode extending through the first gate electrode along a vertical direction perpendicular to the bottom surface of the substrate,
wherein the first gate electrode is provided around a side surface of the second gate electrode, and
wherein a second work function of the second gate electrode is greater than a first work function of the first gate electrode.

15. The semiconductor memory device of claim 14, wherein the second gate electrode is spaced apart from the device isolation pattern by the first gate electrode.

16. The semiconductor memory device of claim 14, wherein a top surface of the first gate electrode has a first width in a second direction crossing the first direction,
wherein a top surface of the second gate electrode has a second width in the second direction, and
wherein the first width is larger than the second width.

17. The semiconductor memory device of claim 14, further comprising a third gate electrode on the first gate electrode,
wherein a top surface of the third gate electrode has a third width in a second direction crossing the first direction,
wherein a top surface of the second gate electrode has a second width in the second direction, and
wherein the third width is larger than the second width.

18. The semiconductor memory device of claim 14, wherein a top surface of the second gate electrode is located at a level, which is equal to or higher than a top surface of the first gate electrode along the vertical direction.

19. The semiconductor memory device of claim 14, wherein the first gate electrode comprises a first region, which is adjacent to the second gate electrode in the first direction, and a second region, which is adjacent to the second gate electrode in a second direction crossing the first direction, and
wherein, along the vertical direction, a bottom surface of the second gate electrode is located at a level, which is equal to or lower than a bottom surface of the first region and is lower than a bottom surface of the second region.

20. A semiconductor memory device, comprising:
an active pattern provided on a substrate and enclosed by a device isolation pattern;
a word line crossing the active pattern and the device isolation pattern in a first direction parallel to a bottom surface of the substrate, the word line comprising a first gate electrode and a second gate electrode, which are adjacent to each other in the first direction;
a bit line provided on the active pattern and extended in a second direction crossing the first direction;
a bit line contact between the active pattern and the bit line;
a storage node contact on the active pattern;
a landing pad on the storage node contact; and
a data storage pattern on the landing pad,
wherein a second work function of the second gate electrode is greater than a first work function of the first gate electrode.
